(19) United States
(12) Patent Application Publication
(10) Pub. No.: US 2006/0088729 A1
(43) Pub. Date: Apr. 27, 2006

(54) White organic light-emitting devices with improved performance

(75) Inventors: William J. Begley, Webster, NY (US); Tukaram K. Hatwar, Penfield, NY (US); Manju Rajeswaran, Fairport, NY (US); Natasha Andrievsky, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/972,671

(22) Filed: Oct. 25, 2004

(51) Int. Cl. H01L 51/54; H05B 33/14

(52) U.S. Cl. 428/690; 428/917; 428/212; 313/504; 313/506; 257/E51.026; 257/E51.022

(57) ABSTRACT

An OLED device produces white light and comprises (A) a red light emitting layer and (B) a blue light emitting layer wherein the red light emitting layer contains a certain type of electroluminescent component having a first bandgap, a non-electroluminescent component having a second bandgap, and one or more further non-electroluminescent components having further bandgaps in which the bandgaps all have a specified relationship.

### CROSS REFERENCE TO RELATED APPLICATIONS

Reference is made to commonly assigned U.S. Ser. No. 10/334,324, filed Dec. 31, 2002 by Christopher T. Brown, et al., entitled “Efficient Electroluminescent Device”; U.S. Ser. No. 10/658,010, filed Sep. 9, 2003 by Christopher T. Brown, et al., entitled “Efficient Electroluminescent Device”; U.S. Ser. No. 10/644,245 filed Aug. 20, 2003, by Tukaram K. Hatwar, et al., entitled “White Light-Emitting Device With Improved Doping”; and U.S. Ser. No. 10/801,997 filed Mar. 16, 2004 by William J. Begley, et al., entitled “White Organic Light-Emitting Devices With Improved Performance”.

### FIELD OF THE INVENTION

This invention relates to an organic white light emitting diode (OLED) electroluminescent (EL) device and more particularly comprising a red light-emitting component, containing at least one electroluminescent compound (ELC) and at least two non-electroluminescent compounds (non-ELCs), and a blue light-emitting component.

### BACKGROUND OF THE INVENTION

An OLED device includes a substrate, an anode, a hole-transporting layer made of an organic compound, an organic luminescent layer with suitable light emitting materials, also known as dopants or electroluminescent compounds, an organic electron-transporting layer, and a cathode. OLED devices are attractive because of their low driving voltage, high luminance, wide-angle viewing and capability for full-color flat emission displays. Tang et al., described this multilayer OLED device in their U.S. Pat. Nos. 4,769,292 and 4,885,211.

There have been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a non-electroluminescent compound (non-ELC) doped with a guest material—an electroluminescent compound (ELC), which results in an efficiency improvement and allows color tuning.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others. Notwithstanding these developments, there are continuing needs for organic EL device components that will provide white light producing OLED devices with high luminance efficiencies combined with high color purity, long lifetimes and low operating voltages.

Efficient white light producing OLED devices are considered as low cost alternative for several applications such as paper-thin light sources, backlights in LCD displays, automotive dome lights, and office lighting. White light producing OLED devices should be bright, efficient, and generally have Commission International d'Eclairage (CIE) chromaticity coordinates of about (0.33, 0.33). In any event, in accordance with this disclosure, white light is that light which is perceived by a user as having a white color.

The DCM class of compounds, or 4-dicyanomethylene-4H-pyrans, as disclosed in EP-A-1,162,674; US-A-2002/0,127,427 and U.S. Pat. No. 5,908,581, is a class of electroluminescent compounds useful for a red electroluminescent component in the production of white light producing OLED devices.

Another useful class of red electroluminescent compounds is the periflanthene class of materials as disclosed in EP-A-1,148,109; EP-A-1,235,466; EP-A-1,182,244; U.S. Pat. No. 6,004,685; Bard et al [J. Organic Chemistry, Vol. 62, Pages 530-537, 1997; J. American Chemical Society, Vol. 118, Pages 2374-2379, 1996]. These materials are characterized by a “perylene-type” emission in the red region of the visible spectrum and are also useful for red electroluminescent components in the production of white light producing OLED devices.

The following patents and publications disclose the preparation of organic OLED devices capable of emitting white light, comprising a hole-transporting layer and an organic luminescent layer, and interposed between a pair of electrodes.

White light producing OLED devices have been reported before by J. Shi (U.S. Pat. No. 5,683,823) wherein the luminescent layer includes red and blue light-emitting materials uniformly dispersed in a host emitting material. This device has good electroluminescent characteristics, but the concentration of the red and blue dopants are very small, such as 0.12% and 0.25% of the host material. These concentrations are difficult to control during large-scale manufacturing. Sato et al., in JP 07,142,169 discloses an OLED device, capable of emitting white light, made by placing a blue light-emitting layer next to the hole-transporting layer and followed by a green light-emitting layer having a region containing a red fluorescent layer.

Kido et al., in Science, Vol. 267, p. 1332 (1995) and in Applied Physics Letters, Vol. 64, p. 815 (1994), report a white light producing OLED device. In this device three emitter layers with different carrier transport properties, each emitting blue, green or red light, are used to generate white light. Littman et al., in U.S. Pat. No. 5,405,709 disclose another white emitting device, which is capable of emitting white light in response to hole-electron recombination, and comprises a fluorescent in a visible light range from bluish green to red. Recently, Deshpande et al., in Applied Physics Letters, Vol. 75, p. 888 (1999), published white OLED device using red, blue, and green luminescent layers separated by a hole-blocking layer.

Ara et. al., in U.S. Pat. No. 6,613,454 describes an organic EL device with at least one of the organic layers containing at least one organic compound selected from a given list of compounds. One class of organic compounds in U.S. Pat. No. 6,613,454 is naphthacene-based and includes 5,6,11,12-tetra-(2′-naphthalenyl)naphthacene (NR). Again there is no teaching of naphthacene-based compounds having the same single substituent at both ends of the naphthacene nucleus and on two of the phenyl groups of the naphthacene.

However, these devices do not have the desired EL characteristics in terms of luminance, chromaticity and stability of the components in the devices.

It is a problem to be solved therefore to provide an OLED device having a light-emitting layer (LEL) that exhibits improved luminance, stability and white light characteristics.

### SUMMARY OF THE INVENTION

The invention provides an OLED device that produces white light comprising (A) a red light emitting layer and (B) a blue light emitting layer wherein said red light emitting layer contains an electroluminescent component having a first bandgap, a non-electroluminescent component having a second bandgap, and one or more further non-electroluminescent components having further bandgaps, wherein:
i) the second bandgap is equal to or greater than the first bandgap but is not more than 2.7 eV;
ii) each of the one or more further bandgaps is greater than the first and second bandgaps;
iii) the non-electroluminescent componene with the second bandgap is present in an amount of 0.1 to 99.8 vol. percent of the total material in the red light emitting layer;
iv) the one or more non-electroluminescent components with further bandgaps are present in a combined amount of 0.1 to 99.8 vol. percent of the total material in the red light emitting layer;
v) the electroluminescent component is present in an amount of 0.1 to 5 vol. percent of the total material in the light emitting layer; and
vi) the non-electroluminescent component with the second bandgap is represented by formula (Ia); 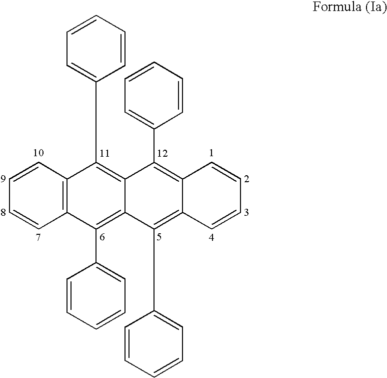
   wherein:
a) any hydrogen on the phenyl rings in the 6- and 12-positions may be substituted;
b) there are identical substituent groups at the 2- and 8-positions; and
c) the phenyl rings in the 5- and 11-positions contain only para-substituents identical to the substituent groups in paragraph b).

The invention also provides a display including such a device and a method of emitting light using such a device.

Such a device exhibits improved luminance and stability characteristics.

### BRIEF DESCRIPTION OF THE DRAWINGS

FIG. 1 depicts a white light producing EL device wherein the hole-transporting layer includes a light-emitting material.

FIG. 2 depicts another structure of a white light producing EL device wherein the hole-transporting layer has two sub layers, one of which includes a light-emitting material.

FIG. 3 depicts another structure of a white light producing EL device wherein the electron-transporting layer has two sub layers, one of which includes a light-emitting material. The hole-transporting layer also includes a light-emitting material.

FIG. 4 depicts another structure of a white light producing EL device wherein the electron-transporting layer has two sub layers, one of which includes a light-emitting material. The hole-transporting layer also has two sub layers one of which includes a light-emitting material.

FIG. 5 depicts another structure of a white light producing OLED device wherein the electron-transporting layer has three sub layers, two of which include light-emitting materials. The hole-transporting layer also includes a light-emitting material.

FIG. 6 depicts another structure of a white light producing OLED device wherein the electron-transporting layer has three sub layers, two of which include light-emitting materials. The hole-transporting layer also has two sub layers one of which includes a light-emitting material.

### DETAILED DESCRIPTION OF THE INVENTION

The invention is generally as described above.

An OLED device of the invention is a multilayer electroluminescent device capable of producing white light from a red light-emitting component and a blue light-emitting component. The OLED device comprises a substrate, a cathode, an anode, a hole transport layer (HTL), an electron transport layer (ETL) and a light-emitting layer (LEL). The hole transport layer and the electron transport layer may be comprised of further sub layers. The red light-emitting component further comprising at least two non-electroluminescent compounds (non-ELCs) with second and further bandgaps, and at least one electroluminescent compound (ELC), such as a periflanthene or a pyran. In a further embodiment of the invention the red light-emitting component comprises a non-electroluminescent compound (non-ELC) with a second bandgap, at least two non-electroluminescent compounds having further bandgaps and at least one electroluminescent compound (ELC), such as a periflanthene or a pyran. The OLED device may include other layers such as charge-injecting layers, charge-transporting layers, and blocking layers.

As used herein, the term “component” is used interchangeably with “compound” and both are understood to include not only a separate compound but also the corresponding portion of a polymeric compound. The term electroluminescent component means a component which, in the combination, electroluminesces in the range of 400-700 nm. The term non-electroluminescent component means a component which, in the combination, does not significantly electroluminesce in the range of 400-700 nm.

The term light-emitting layer means that the layer comprises at least one electroluminescent component.

The term periflanthene is a trivial name describing the central diindenoperylene structure of dibenzo {[f,f′]-4,4′,7,7′-tetraphenyl } -diindeno[1,2,3-cd: 1′,2′,3′-lm]perylene. The diindenoperylene core is composed of two indene fusions with the 1,2,3-positions of an indene and the cd and lm faces of a perylene. [The Naming and Indexing of Chemical Substances for Chemical Abstracts-A Reprint of Index IV (Chemical Substance Index Names) from the Chemical Abstracts—1992 Index Guide; American Chemical Society: Columbus, Ohio, 1992; paragraph 135, 148 and 150. The first description of a periflanthene was in 1937 (Braun, J.; Manz, G., Ber. 1937, 70, 1603). In this case indene can also include analogous materials wherein the benzo-group of indene can be a ring of 5, 6, or 7 atoms comprising carbon or heteroatoms such as nitrogen, sulfur or oxygen.

The compound designated as Inv-1, and related “diindenoperylene” compounds Inv-2 through Inv-11, can be prepared via standard accepted protocols involving aluminum(III)chloride (Braun, J.; Manz, G., Ber. 1937, 70, 1603), cobalt(III)fluoride (Debad, J. D.; Morris, J. C.; Lynch, V.; Magnus, P.; Bard, A. J. Am. Chem. Soc. 1996, 118, 2374-2379) and thallium trifluoracetate (Feiler, L.; Langhals, H.; Polbom, K. Liebigs Ann. 1995, 1229-1244).

Suitably, the red light-emitting layer of the device comprises at least two non-electroluminescent compounds and at least one electroluminescent compound where the electroluminescent compound is present in an amount of 0.1 to 5% of the total material of the light emitting layer, more typically from 0.1-2.0% of the total material of the light emitting layer. This electroluminescent compound has a first bandgap. The non-electroluminescent compounds function as an initial “energy capture agent” that transfers that energy to the electroluminescent compound or guest material as the primary light emitter. The non-electroluminescent component comprises at least two non-electroluminescent compounds with second and further bandgaps, respectively. The non-electroluminescent compound with a second bandgap is present in the red light-emitting layer in an amount of 0.1 to 99.8% of the total material and the non-electroluminescent compound with a further bandgap is also present in the red light-emitting layer in an amount of 0.1 to 99.8% of the total layer. The total amount of non-electroluminescent compounds amounts to at most 99.9% of the material of the red light-emitting layer, with the electroluminescent compound accounting for the remainder. Desirably, the amount of the non-electroluminescent compound with the second bandgap present in the red light-emitting layer is in an amount of 5 to 95% of the total material of the light-emitting layer with more typically, 10 to 75% being employed. The remainder of the material is made up of the non-electroluminescent compound or compounds with the further bandgap or bandgaps and the electroluminescent compound or compounds.

One useful embodiment of the invention is one where the non-electroluminescent compound with the second bandgap is represented by Formula (Ib): 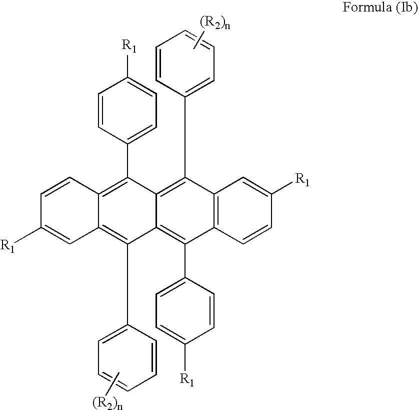
wherein
R₁ and R₂ are substituent groups;
n is 1-5;
provided that the R₁ groups are the same; and
provided further, that the R₂ groups, their location and n value on one ring are the same as those on the second ring.

A particularly useful embodiment of the non-electroluminescent compound of Formula (Ib) is one in which R₁ is represented by the formula; 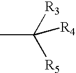
wherein each of R₃, R₄ and R₅ is hydrogen or an independently selected substituent or R₃, R₄ and R₅ taken together can form a mono- or multi-cyclic ring system. Particularly useful R₃, R₄ and R₅ groups are alkyl groups. When R₃, R₄ and R₅ are alkyl groups, specifically useful groups are methyl groups.

Embodiments of the electroluminescent components in the red light emitting layer useful in the invention provide for an emitted light having a red hue. Substituents can also be selected to fine-tune the hue of the emitted light. Substituents are also selected to provide embodiments that exhibit a reduced loss of initial luminance compared to the device containing no diindenoperylene of claim 1.

Formula (II) suitably represents electroluminescent compounds useful in the red emitting layers of the invention: 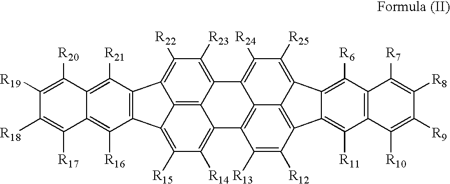
wherein:
R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are independently selected as hydrogen or substituents;
provided that any of the R₆ through R₂₅ substituents may join to form further fused rings.

A useful and convenient embodiment is where R₆, R₁₁, R₁₆, and R₂₁, are all phenyl and R₇, R_{8,} R₉, R₁₀, R₁₂, R₁₃, R₁₄, R₁₅, R₁₇, R₁₈, R,₉, R₂₀, R₂₂, R₂₃, R₂₄ and R₂₅ are all hydrogen. A related embodiment is when there are no phenyl groups. Another desirable embodiment is where R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are selected independently from the group consisting of hydrogen, alkyl and aryl.

The emission wavelength of these compounds may be adjusted to some extent by appropriate substitution around the central perylene core.

Further electroluminescent compounds useful in the red emitting layers of the invention are pyran derivatives suitably represented by Formula (III): 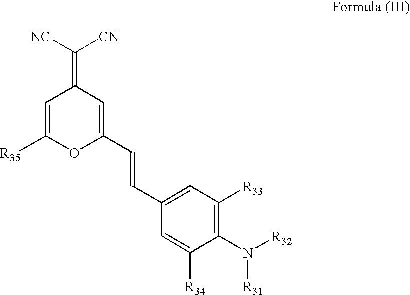
wherein:
R₃₁, R₃₂, R₃₃, R₃₄, and R₃₅ are independently selected as hydrogen or substituents;
provided that any of the indicated substituents may join to form further fused rings.

A useful embodiment is where R₃₁, R₃₂, R₃₃, R₃₄, and R₃₅ are selected independently from the group consisting of halide, alkyl, aryl, alkoxy and aryloxy groups.

A useful and convenient embodiment is where R₃₁, R₃₂, R₃₃, R₃₄, and R₃₅ are selected independently from the group consisting of hydrogen, alkyl and aryl groups.

The electroluminescent component is usually doped into a non-electroluminescent component, which represents the light-emitting layer between the hole-transporting and electron-transporting layers. The non-electroluminescent component is chosen such that there is efficient formation of an excited state on the electroluminescent component thereby affording a bright, highly efficient, stable EL device.

Non-electroluminescent compounds with further bandgap(s) useful in the invention are any of those known in the art that meet the band gap requirements of the invention and are suitably represented by Formula (IV): 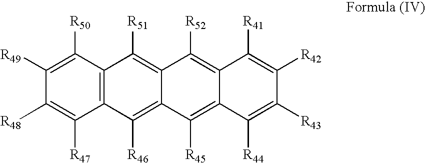
wherein:
R₄, R₄₂, R₄₃, R₄₄, R₄₅, R₄₆, R₄₇, R₄₈, R₄₉, R₅₀, R₅₁, and R₅₂ are independently selected as hydrogen or substituents;
provided that any of the indicated substituents may join to form further fused rings.

A useful and convenient embodiment is where at least one of R₄₁, R₄₂, R₄₃, R₄₄, R₄₅, R₄₆, R₄₇, R₄₈, R₄₉, R₅₀, R₅₁, and R₅₂ are independently selected from the group consisting of halide, alkyl, aryl, alkoxy and aryloxy groups.

The benefit imparted by the electroluminescent compound in the red emitting layer does not appear to be non-electroluminescent compound specific. Desirable non-electroluminescent compound(s) with the further bandgap(s) include those based on chelated oxinoids, benzazoles, anthracenes, tetracenes or tetrarylbenzidines although they are not limited to these five classes of non-electroluminescent compounds. Particular examples of non-electroluminescent compounds with the further bandgap(s) are tris(8-quinolinolato)aluminum (III) (AlQ₃, Inv-27); 2,2′,2′-(1,3,5-benzenetriyl)tris[1-phenyl-1H-benzimidazole] (TPBI); 2-tert-butyl-9,10-di-(2-naphthyl)anthracene (TBADN, Inv-22); 5,6,11,12-tetraphenylnaphthacene (Rubrene, Inv-20); 4,4′-Bis[N-(1-naphthyl)-N-phenylamino]biphenyl (NPB, Inv-24); 4,4′-Bis[N-(1-naphthyl)-N-(2-naphthyl)amino]biphenyl (TNB, Inv-25); 5,12-bis[2-(5-methylbenzothiazolyl)phenyl]-6,1 1-diphenylnaphthacene (DBZR, Inv-21); 5,12-bis[4-tert-butylphenyl]naphthacene (tBDPN, Inv-23), 5,6,11,12-tetra-2-naphthalenylnaphthacene (NR, Inv-20); 9,10-bis(2-naphthyl)-2-phenylanthracene (Inv-26), and 9-(2-naphthyl)-10-(4-phenyl)phenylanthracene (Inv-28).

The EL device of the invention is useful in any device where stable light emission is desired such as a lamp or a component in a static or motion imaging device, such as a television, cell phone, DVD player, or computer monitor.

Examples of electroluminescent compounds with a first bandgap useful in the invention are diindeno[1,2,3-cd]perylene, illustrated in the formulae Inv-1 through Inv-11, and pyran, illustrated in formulae Inv-12 through Inv-18. Examples of non-electroluminescent compounds with a second bandgap useful in the invention are illustrated in formulae Inv-30 through Inv-39. Examples of non-electroluminescent compounds with a further bandgap useful in the invention are naphthacene, indeno[1,2,3-cd]perylene, chelated oxinoid, anthracenyl and N,N′,N,N′-tetraarylbenzidine and are illustrated in Inv-19 through Inv-29. At least one non-electroluminescent compound with a further bandgap can be selected from Inv-19 through Inv-29. In a further embodiment of the invention two or more non-electroluminescent compounds with further bandgaps can be selected from Inv-19 through Inv-29.

The non-electroluminescent compounds useful in the invention for the blue light emitting layer component (B) can be selected from Inv-22, Inv-24, Inv-25, Inv-26, Inv-28 and Inv-40, but it should be understood that any suitable non-electroluminescent compound useful for the blue emitting layer known in the art may be used. Electroluminescent compounds useful in the invention for the blue light emitting layer component (B) can be selected from Inv-41, Inv-42, Inv-43, and Inv-44, but it should be understood that any suitable electroluminescent compound useful for the blue emitting layer known in the art may be used.

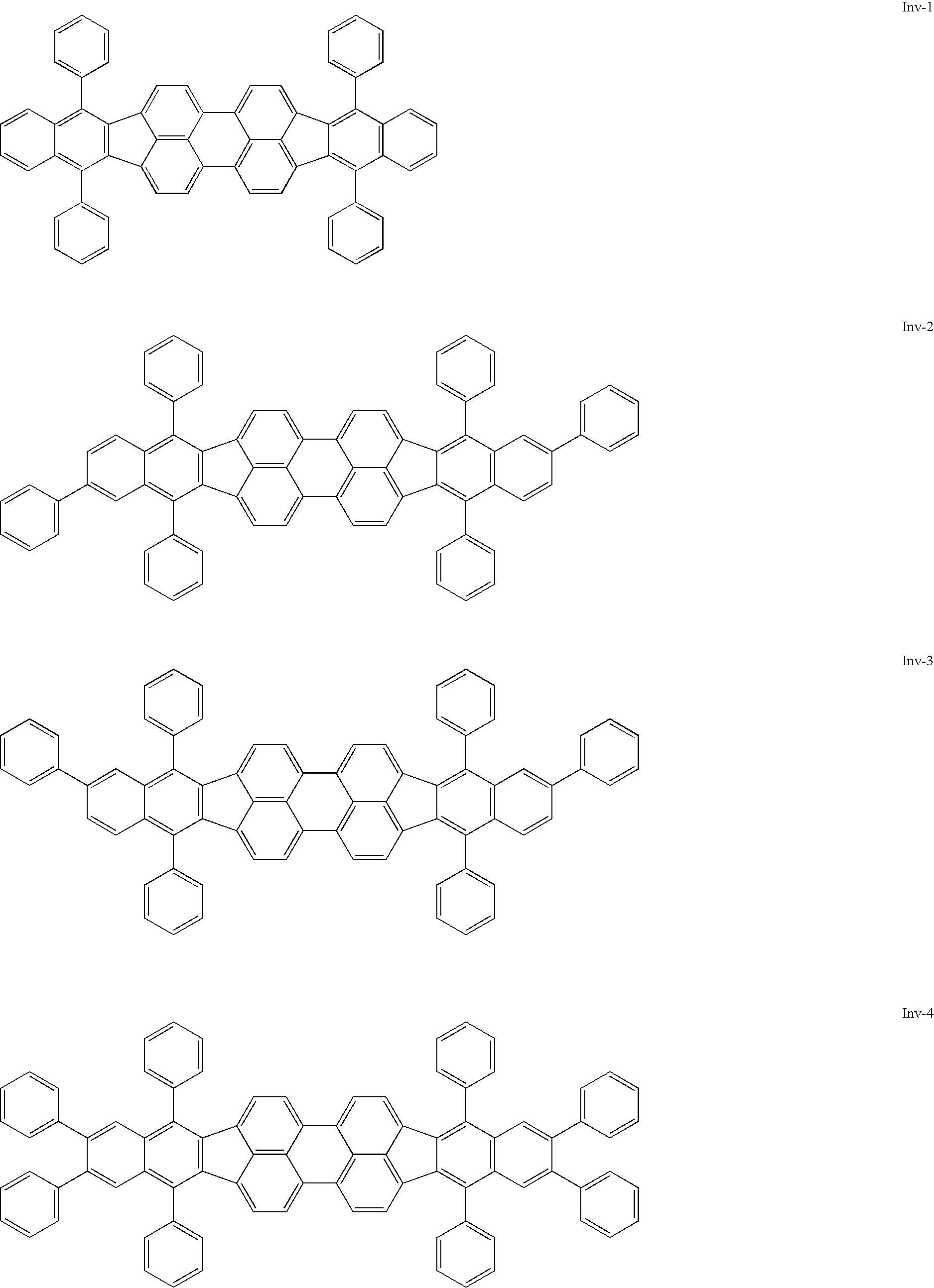

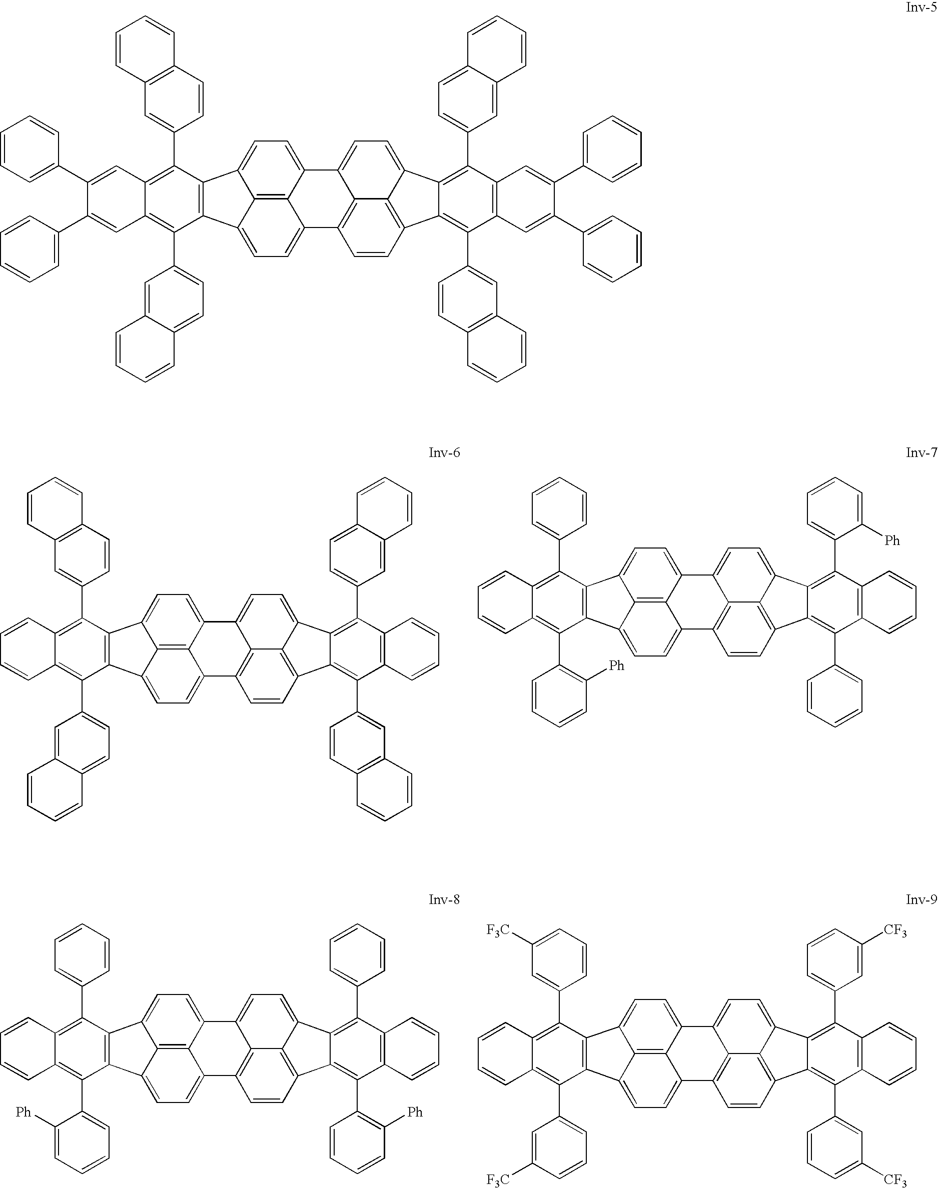

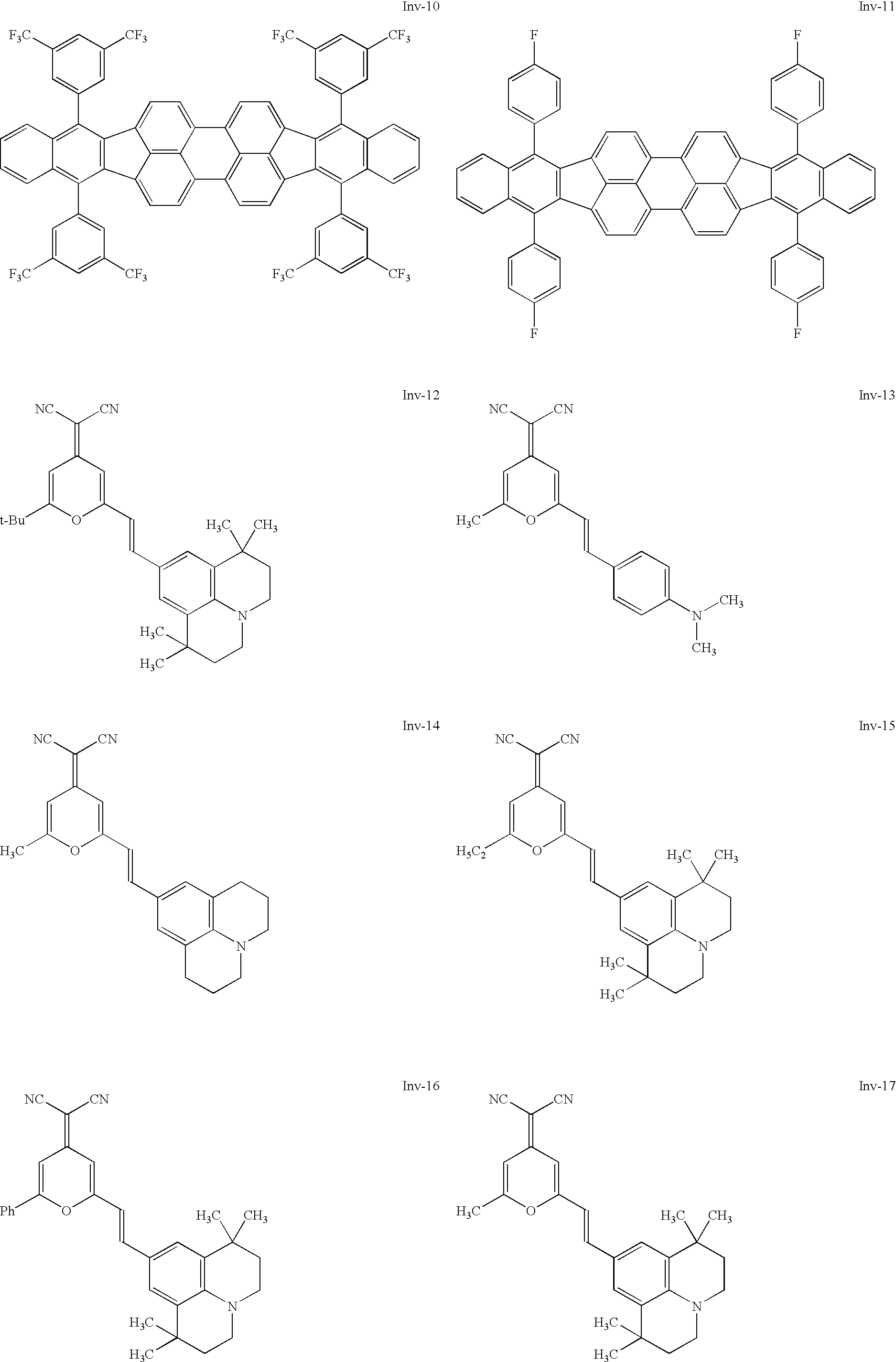

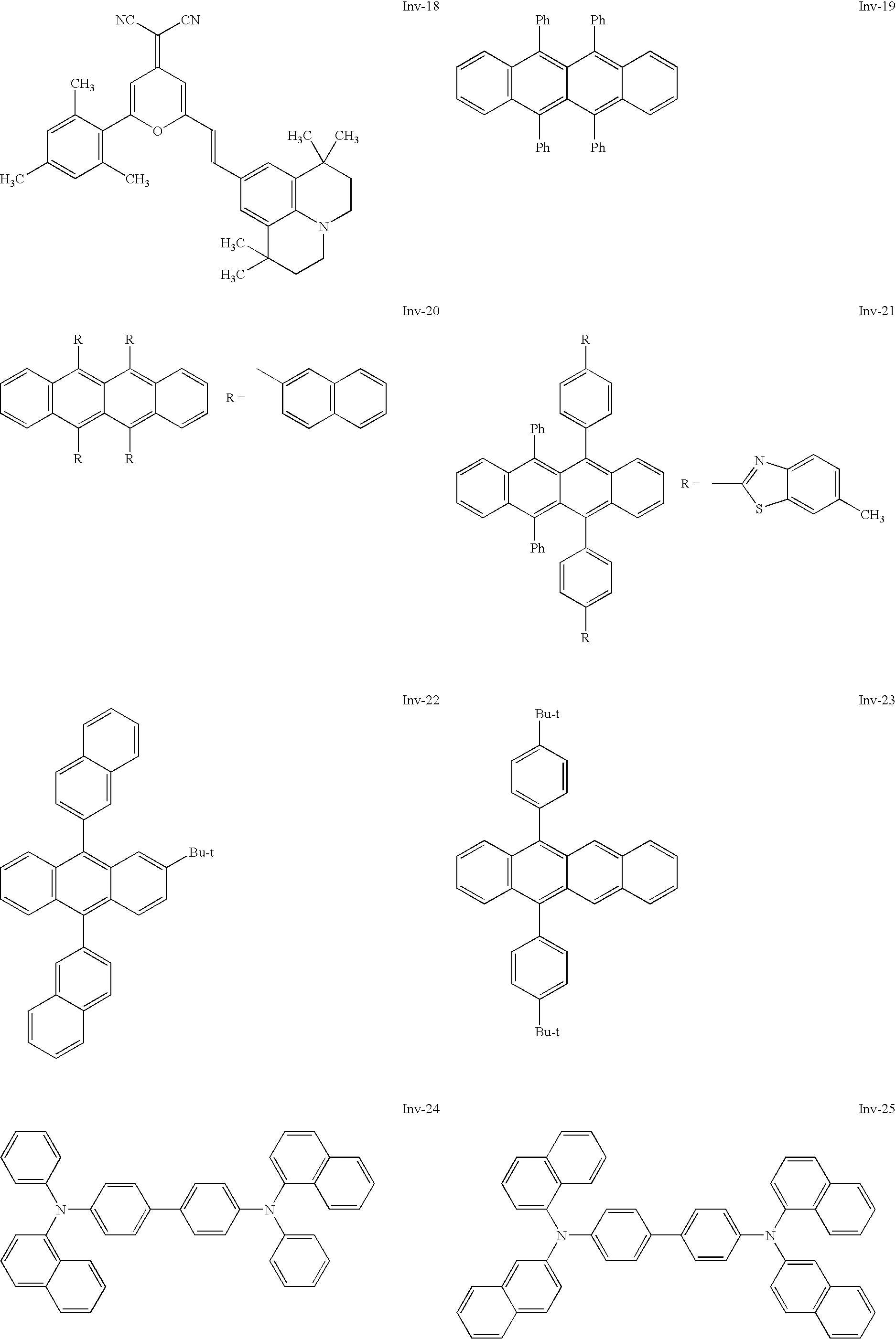

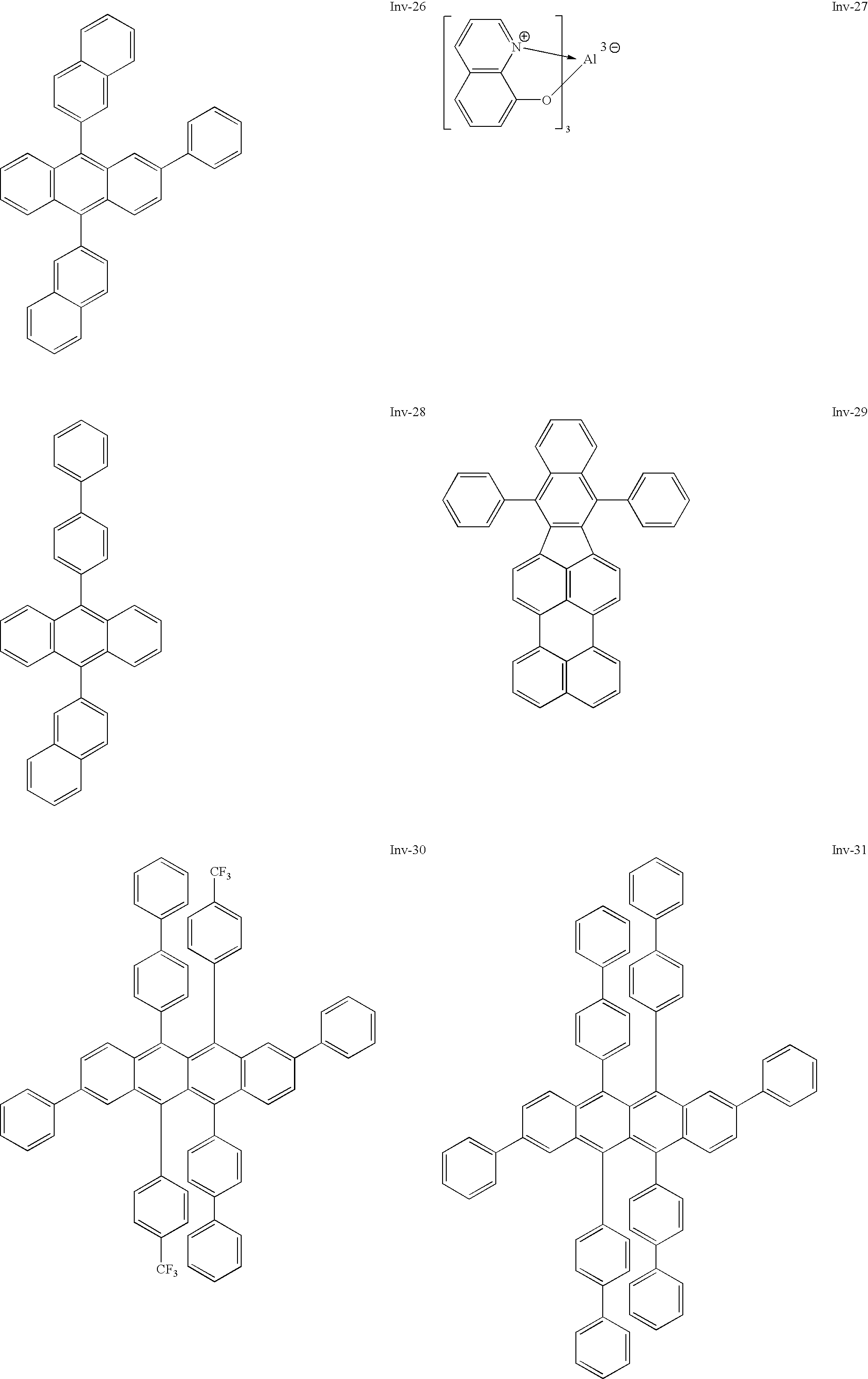

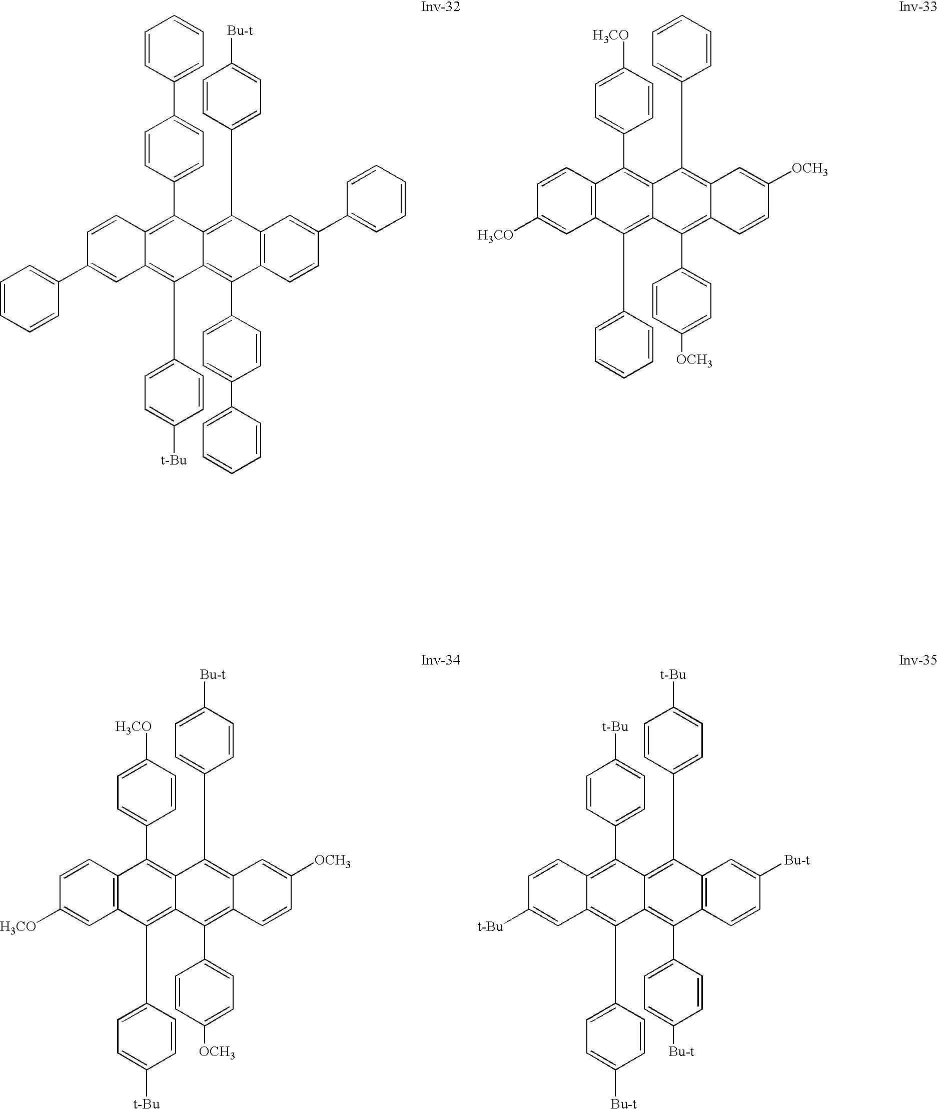

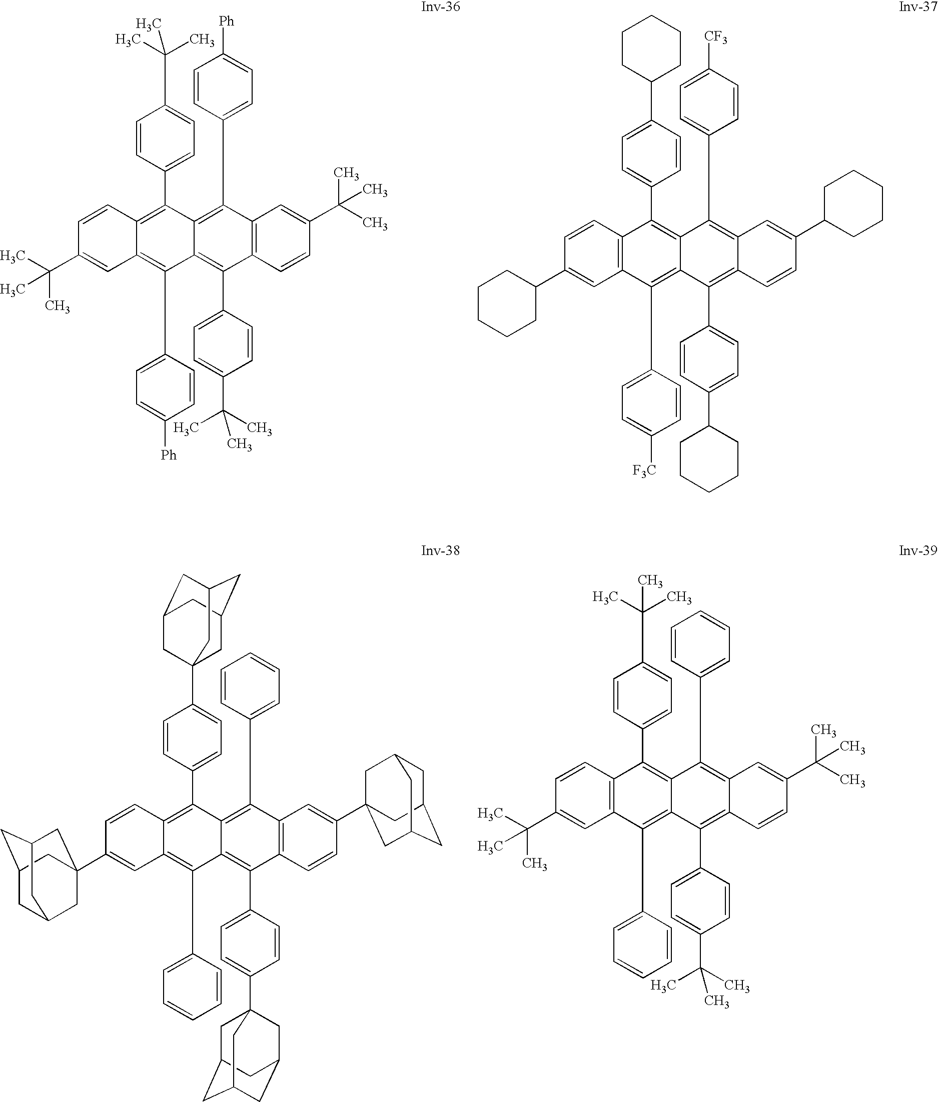

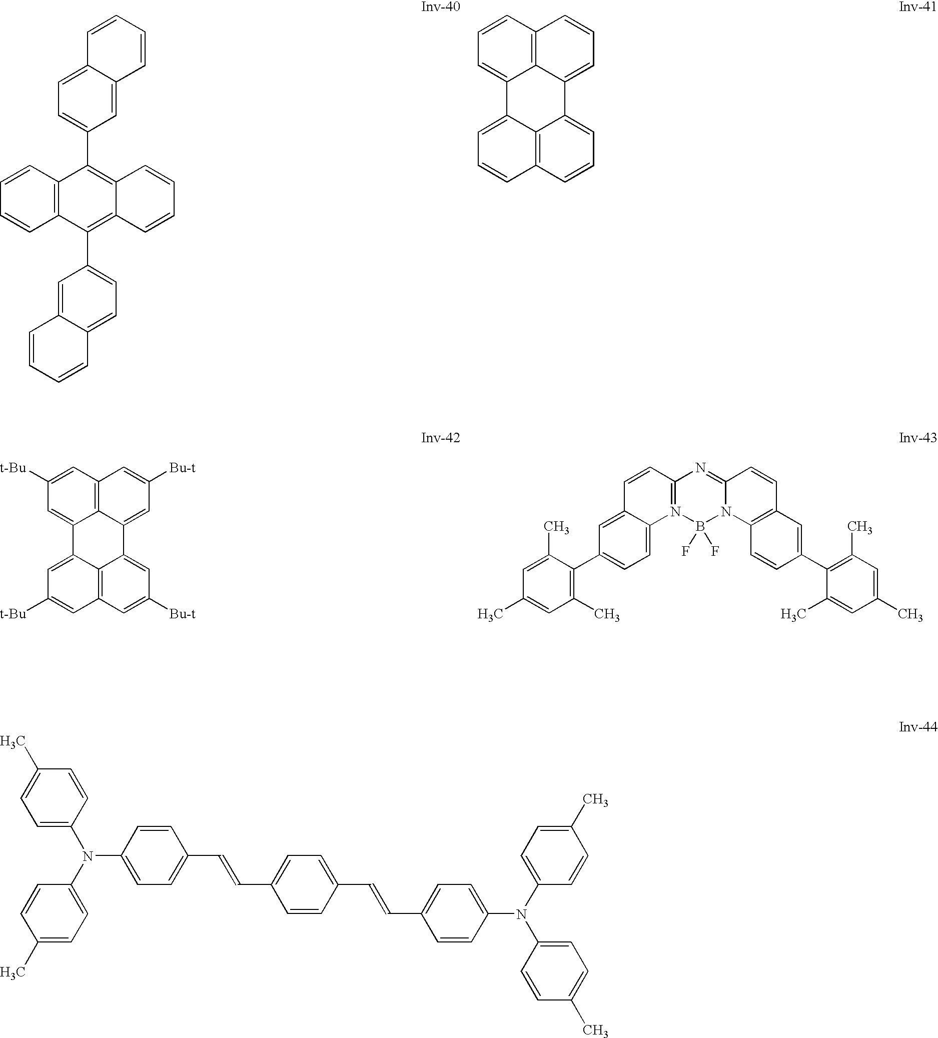

In one embodiment of the invention, the component with the second bandgap comprises 5 to 95% of the layer and in another embodiment the component with the second bandgap comprises 10 to 75% of the layer. In a useful embodiment of the invention, the component with the second bandgap comprises 5 to 95% of the layer and the electroluminescent component is a periflanthene or a pyran. In yet another useful embodiment of the invention, the component with the second bandgap comprises 10 to 75% of the layer and the electroluminescent component is a periflanthene or a pyran. The electroluminescent compound, but specifically the periflanthene or a pyran materials, can be present in the range of 0.1 to 5% of the total material in the red light emitting layer, but is typically in the range of 0.3 to 1.5%.

In another embodiment, the component with the second bandgap comprises 5 to 95% of the layer and the components with the further bandgaps are selected from a specified listing of tris(8-quinolinolato)aluminum (III) (Alq₃); 2,2′,2′-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 4,4′-Bis[N-( 1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene; and in a still further embodiment there are present at least two components with a further bandgap comprising at least one selected from tris(8-quinolinolato)aluminum (III) (Alq₃); 2,2′,2′-(1,3,5-benzenetriyl)tris[ 1-phenyl- 1 H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino( 1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)- 10-(4-phenyl)phenylanthracene.

In an additional embodiment, the component with the second bandgap comprises 10 to 75% of the layer and the components with the further bandgaps are selected from a specified listing of tris(8-quinolinolato)aluminum (III) (Alq₃); 2,2′,2′-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene; and in a still further embodiment there are present at least two components with a further bandgap comprising at least one selected from tris(8-quinolinolato)aluminum (III) (Alq₃); 2,2′,2′-(1,3,5-benzenetriyl)tris[1-phenyl- 1 H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene.

Typical embodiments of the invention provide not only improved drive voltage but can also provide improved luminance efficiency, operational stability and color purity (chromaticity).

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo- 1-oxazolidinyl, 3-dodecyl-2,5-dioxo- 1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methyl sulfonamido, benzenesulfonamido, p-tolyl sulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, andp-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with a thin film transistor (TFT).

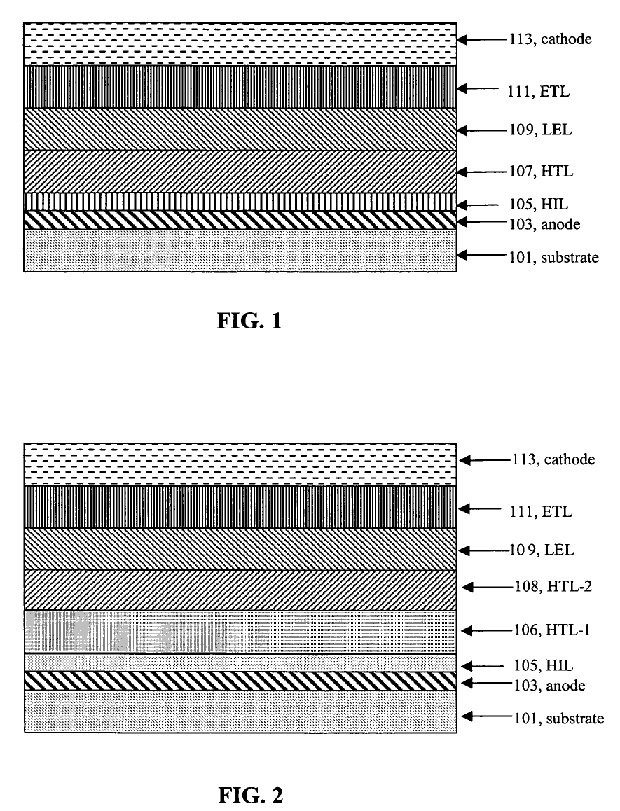

There are numerous configurations of the organic layers wherein the present invention can be successfully practiced. Essential requirements are a cathode, an anode, a HTL and a LEL. A more typical structure is shown in FIG. 1 and contains a substrate 101, an anode 103, an optional hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the. anode or cathode. Also, the total combined thickness of the organic layers is preferably less than 500 nm.

The following are non-limiting examples of white EL devices. In each case the device contains (A) a red light emitting layer and (B) a blue or blue-green light emitting layer wherein the red light emitting layer contains at least one electroluminescent compound having a first bandgap and at least two non-electroluminescent compounds having second and further bandgaps, respectively wherein the non-electroluminescent compound having the second bandgap is of Formula (Ib).

Layer 107 is also a light-emitting layer. In one embodiment, 107 is a red light-emitting cmponent (A) and 109 is a blue or blue-green light-emitting component (B).

FIG. 2, depicts an organic white light-emitting device which is similar to that shown in FIG. 1, except that the hole-transporting layer 107 comprises two sub layers, layer 106 and layer 108.

In one desirable embodiment, layer 108 includes a red light-emitting component (A) and layer 109 includes a blue or blue-green light-emitting component (B).

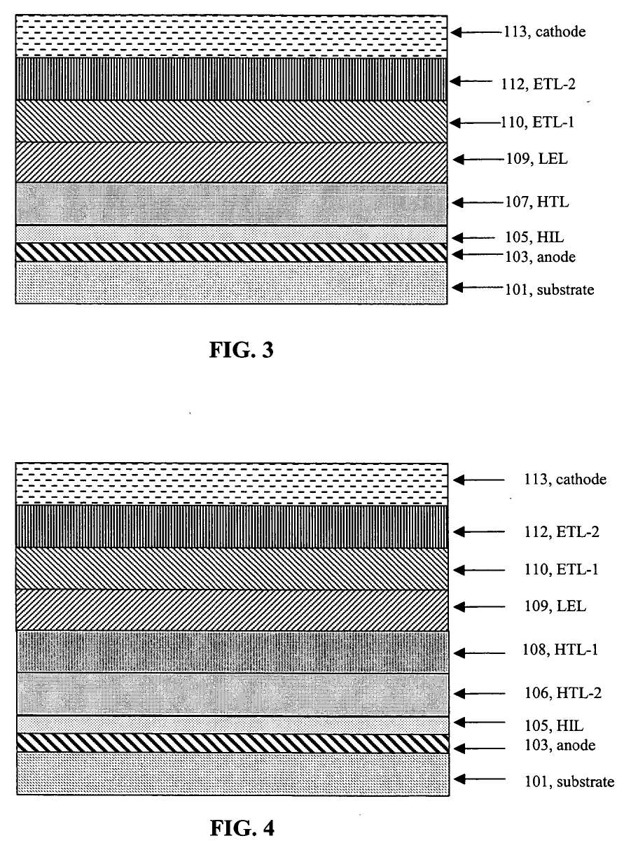

FIG. 3 depicts an organic white light-emitting device, which is similar to FIG. 1 except electron-transporting layer 111 comprises two sub layers, 110 and 112.

In one desirable embodiment, layer 110 includes a red light-emitting component (A) and layer 109 includes a blue or blue-green light-emitting component (B).

In another desirable embodiment, layer 107 includes a red light-emitting component (A) and layer 110 also includes a red light-emitting component (A) which may be the same or different. Layer 109 includes a blue or blue-green light-emitting component (B).

In another desirable embodiment layer 110 includes a green light-emitting component, layer 109 includes a blue light-emitting component (B), and layer 107 includes a red light-emitting component (A).

FIG. 4 depicts an organic white light-emitting device, which is similar to FIG. 1 except that the hole-transporting layer 107 comprises two sub layers, layer 106 and layer 108, and the electron-transporting layer 111 comprises two sub layers, 110 and 112.

In one desirable embodiment layer 108 includes a red light-emitting component (A) and layer 110 also includes a red light-emitting component (A) wherein the materials may be the same or different. Layer 109 includes a blue or blue-green light-emitting component (B).

In another desirable embodiment, layer 108 includes a red light-emitting component (A), layer 109 includes a blue or blue-green light-emitting component (B), and layer 110 includes a green light-emitting component (B).

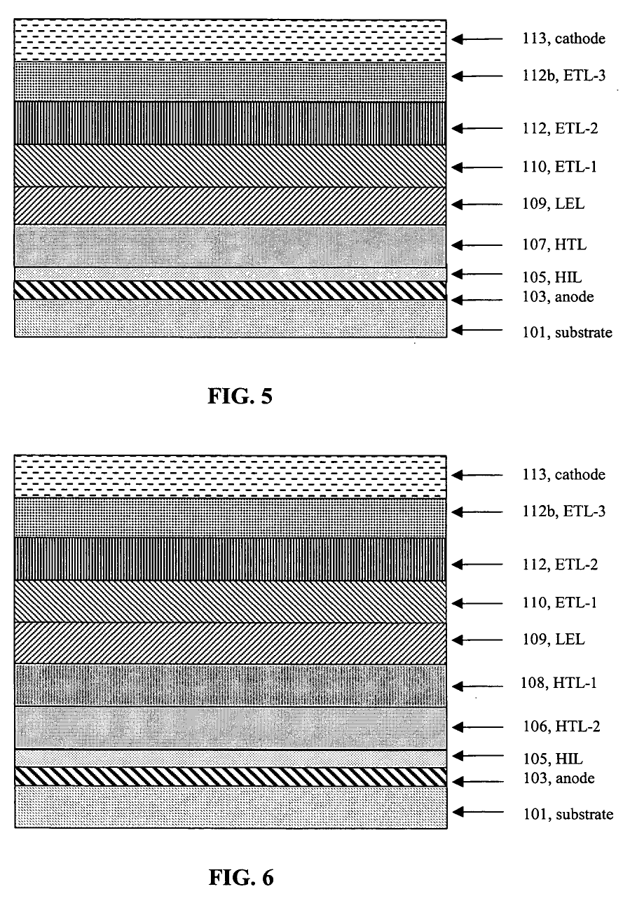

FIG. 5 depicts an organic white light-emitting device, which is similar to FIG. 1 except that the electron-transporting layer 111 comprises three sub layers, 110, 112, and 112b.

In one desirable embodiment layer 112 includes a green light-emitting component, layer 110 includes a red light-emitting component (A) and layer 109 includes a blue or blue-green light-emitting component (B). Layer 107 also includes a red light-emitting component (A) which may be the same or different than that in layer 110.

FIG. 6 depicts an organic white light-emitting device, which is similar to FIG. 1 except that the hole-transporting layer 107 comprises two sub layers, layer 106 and layer 108, and the electron-transporting layer 111 comprises three sub layers, 110, 112, and 112b.

In one desirable embodiment layer 112 includes a green light-emitting material, layer 110 includes a red light-emitting component (A), and layer 109 includes a blue or blue-green light-emitting component (B). Layer 108 includes a red light-emitting component (A) which may be the same or different than that in layer 110.

In FIGS. 1 through 6, the hole injection layer is shown, but it should be understood that this layer is optional, it may or may not be present in the various device structures. An electron injection layer, which is not shown in the figures, is also optional.

The anode and cathode of the OLED are connected to a voltage/current source through electrical conductors. The OLED is operated by applying a potential between the anode and cathode such that the anode is at a more positive potential than the cathode. Holes are injected into the organic EL element from the anode. Enhanced device stability can sometimes be achieved when the OLED is operated in an AC mode where, for some time period in cycle, the potential bias is reversed and no current flows. An example of an AC driven OLED is described in U.S. Pat. No. 5,552, 678.

Substrate

The substrate 101 can either be light transmissive or opaque, depending on the intended direction of light emission. The light transmissive property is desirable for viewing the EL emission through the substrate. Transparent glass or organic material are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials. Of course it is necessary to provide in these device configurations a light-transparent top electrode.

Anode

The conductive anode layer 103 is commonly formed over the substrate and, when EL emission is viewed through the anode, it should be transparent or substantially transparent to the emission of interest. Common transparent anode materials used in this invention are indium-tin oxide (ITO) and tin oxide, but other metal oxides can work including, but not limited to, aluminum- or indium-doped zinc oxide (IZO), magnesium-indium oxide, and nickel-tungsten oxide. In addition to these oxides, metal nitrides, such as gallium nitride, and metal selenides, such as zinc selenide, and metal sulfides, such as zinc sulfide, can be used in layer 103. For applications where EL emission is viewed through the top electrode, the transmissive characteristics of layer 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds such as those described in U.S. Pat. No. 4,720,432, and plasma-deposited fluorocarbon polymers such as those described in U.S. Pat. No. 6,208,075. Alternative hole-injecting materials reportedly useful in organic EL devices are described in EP 0 891121 A1 and EP 1029 909 A1.

Hole-Transporting Layer (HTL)

The hole-transporting layer 107 of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. Additionally, the hole-transporting layer may be constructed of one or more layers such that each layer can be doped or un-doped with the same or different light emitting material. The thickness of the HTL can be any suitable thickness. It can be in the range of from 0.1 to 300nm. In one form, the aromatic tertiary amine can be an arylamine, such as a monoarylamine, diarylamine, triarylamine, or a polymeric arylamine group. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A). 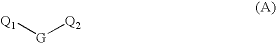
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring group, e.g., a naphthalene. When G is an aryl group, it is conveniently a phenylene, biphenylene, or naphthalene group.

A useful class of triarylamine groups satisfying structural formula (A) and containing two triarylamine groups is represented by structural formula (B): 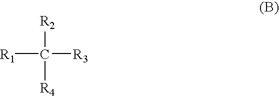
where
R₁ and R₂ each independently represents a hydrogen atom, an aryl group, or an alkyl group or R₁ and R₂ together represent the atoms completing a cycloalkyl group; and
R₃ and R₄ each independently represents an aryl group, which is in turn substituted with a diaryl substituted amino group, as indicated by structural formula (C): 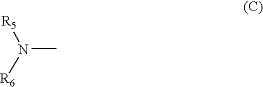
   wherein R₅ and R₆ are independently selected aryl groups. In one embodiment, at least one of R₅ or R₆ contains a polycyclic fused ring group, e.g., a naphthalene.

Another class of aromatic tertiary amine groups are the tetraaryldiamines. Desirable tetraaryldiamines groups include two diarylamino groups, such as indicated by formula (C), linked through an arylene group. Useful tetraaryldiamines include those represented by formula (D). 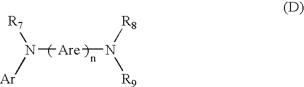
wherein
each Are is an independently selected arylene group, such as a phenylene or anthracene group,
n is an integer of from 1 to 4, and
Ar, R₇, R₈, and R₉ are independently selected aryl groups. In a typical embodiment, at least one of Ar, R₇, R₈, and R₉ is a polycyclic fused ring group, e.g., a naphthalene

The various alkyl, alkylene, aryl, and arylene groups of the foregoing structural formulae (A), (B), (C) and (D), can each in turn be substituted. Typical substituents include alkyl groups, alkoxy groups, aryl groups, aryloxy groups, and halogen such as fluoride, chloride, and bromide. The various alkyl and alkylene groups typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene groups are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylarnine and the electron injecting and transporting layer. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylarnino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′-tetra-2-naphthyl-4,4′-diaminobiphenyl
N-Phenylcarbazole
4,4′-Bis[N-(1-naphthyl)-N-phenylamino]biphenyl(NPB)
4,4′-Bis[N-(1-naphthyl)-N-(2-naphthyl)amino]biphenyl(TNB)
4,4′-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4′-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4′-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4′-tris[(3-methylphenyl)phenylamino]triphenylamine (MTDATA)
4,4′-Bis[N-(3-methylphenyl)-N-phenylamino]biphenyl (TPD

Another class of useful hole-transporting materials includes polycyclic aromatic compounds as described in EP 1009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 109 of the organic EL element comprises a luminescent or fluorescent material where electroluminescence is produced as a result of electron-hole pair recombination in this region. The light-emitting layer can be comprised of a single material, but more commonly consists of non-electroluminescent compounds doped with an electroluminescent guest compound or compounds where light emission comes primarily from the electroluminescent compound and can be of any color. The non-electroluminescent compound or compounds in the light-emitting layer can be an electron-transporting material, as defined below, a hole-transporting material, as defined above, or another material or combination of materials that support hole-electron recombination. The electroluminescent compound is usually chosen from highly fluorescent dyes, but phosphorescent compounds, e.g., transition metal complexes as described in WO 98/55561, WO 00/18851, WO 00/57676, and WO 00/70655 are also useful. Electroluminescent compounds can be coated as 0.01 to 50 % into the non-electroluminescent component material, but typically coated as 0.01 to 30% and more typically coated as 0.01 to 15% into the non-electroluminescent component. The thickness of the LEL can be any suitable thickness. It can be in the range of from 0.1 mm to 100 mm.

An important relationship for choosing a dye as a electroluminescent component is a comparison of the bandgap potential which is defined as the energy difference between the highest occupied molecular orbital and the lowest unoccupied molecular orbital of the molecule. For efficient energy transfer from the non-electroluminescent compound to the electroluminescent compound molecule, a necessary condition is that the band gap of the electroluminescent compound is smaller than that of the non-electroluminescent compound or compounds.

Non-electroluminescent compounds and emitting molecules known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful non-electroluminescent component compounds capable of supporting electroluminescence, and are particularly suitable for light emission of wavelengths longer than 500 nm, e.g., green, yellow, orange, and red. 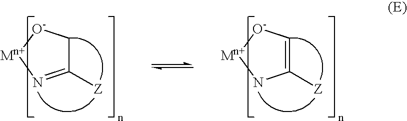
wherein
M represents a metal;
n is an integer of from 1 to 4; and
Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such as aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo {f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]
CO-10: Bis(2-methyl-8-quinolinato)-4-phenylphenolatoaluminum (III)

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

A preferred embodiment of the luminescent layer consists of a host material doped with fluorescent dyes. Using this method, highly efficient EL devices can be constructed. Simultaneously, the color of the EL devices can be tuned by using fluorescent dyes of different emission wavelengths in a common host material. Tang et al. in commonly assigned U.S. Pat. No. 4,769,292 has described this dopant scheme in considerable details for EL devices using Alq as the host material.

Shi et al. in commonly assigned U.S. Pat. No. 5,935,721 has described this dopant scheme in considerable details for the blue emitting OLED devices using 9,10-di-(2-naphthyl)anthracene (ADN) derivatives as the host material.

Derivatives of 9,10-di-(2-naphthyl)anthracene (Formula F) constitute one class of useful non-electroluminescent com pounds capable of supporting electroluminescence, and are particularly suitable for light emission of wavelengths longer than 400 nm, e.g., blue, green, yellow, orange or red. 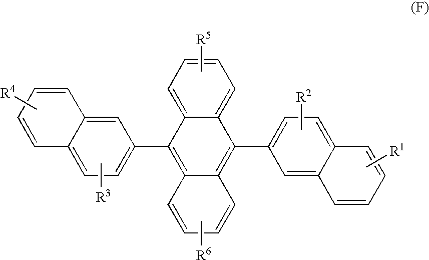
wherein: R¹, R², R³, R⁴, R⁵, and R⁶ represent hydrogen or one or more substituents selected from the following groups:
Group 1: hydrogen, alkyl and alkoxy groups typically having from 1 to 24 carbon atoms;
Group 2: a ring group, typically having from 6 to 20 carbon atoms;
Group 3: the atoms necessary to complete a carbocyclic fused ring group such as naphthyl, anthracenyl, pyrenyl, and perylenyl groups, typically having from 6 to 30 carbon atoms;
Group 4: the atoms necessary to complete a heterocyclic fused ring group such as furyl, thienyl, pyridyl, and quinolinyl groups, typically having from 5 to 24 carbon atoms;
Group 5: an alkoxylamino, alkylamino, and arylamino group typically having from 1 to 24 carbon atoms; and
Group 6: fluorine, chlorine, bromine and cyano radicals.

Illustrative examples include 9,10-di-(2-naphthyl)anthracene (ADN) and 2-t-butyl-9,10-di-(2-naphthyl)anthracene (TBADN). Other anthracene derivatives can be useful as an non-electroluminescent compound in the LEL, such as diphenylanthracene and its derivatives, as described in U.S. Pat. No. 5,927,247. Styrylarylene derivatives as described in U.S. Pat. No. 5,121,029 and JP 08333569 are also useful non-electroluminescent materials for blue emission. For example, 9,10-bis[4-(2,2-diphenylethenyl)phenyl]anthracene, 4,4′-Bis(2,2-diphenylethenyl)-1,1′-biphenyl (DPVBi) and phenylanthracene derivatives as described in EP 681,019 are useful non-electroluminescent materials for blue emission. Another useful non-electroluminescent material capable of supporting electroluminescence for blue-light emission is H-1 and its derivatives shown as follows:

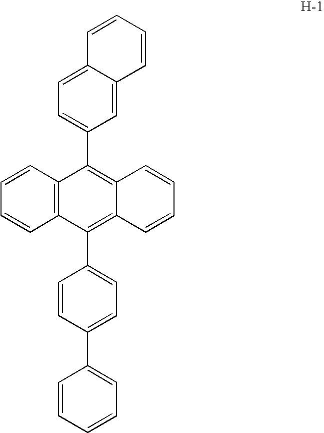

Benzazole derivatives (Formula G) constitute another class of useful non-electroluminescent components capable of supporting electroluminescence, and are particularly suitable for light emission of wavelengths longer than 400 nm, e.g., blue, green, yellow, orange or red. 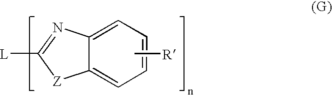
where:
n is an integer of 3 to 8;
Z is —O, —NR or —S where R is H or a substituent; and
R′ represents one or more optional substituents where R and each R′ are H or alkyl groups such as propyl, t-butyl, and heptyl groups typically having from 1 to 24 carbon atoms; carbocyclic or heterocyclic ring groups such as phenyl and naphthyl, furyl, thienyl, pyridyl, and quinolinyl groups and atoms necessary to complete a fused aromatic ring group typically having from 5 to 20 carbon atoms; and halo such as chloro, and fluoro;

L is a linkage unit usually comprising an alkyl or ary group which conjugately or unconjugately connects the multiple benzazoles together.

An example of a useful benzazole is 2,2′, 2″-(1,3,5-phenylene)tris[1-phenyl-1H-benzimidazole], (TPBI).

Distyrylarylene derivatives as described in U.S. Pat. No. 5,121,029 are also useful non-electroluminescent component materials in the LEL.

Desirable fluorescent electroluminescent components include groups derived from fused ring, heterocyclic and other compounds such as anthracene, tetracene, xanthene, perylene, rubrene, pyran, rhodamine, quinacridone, dicyanomethylenepyran, thiopyran, polymethine, pyrilium thiapyrilium, and carbostyryl compounds. Illustrative examples of useful electroluminescent components include, but are not limited to, the following:

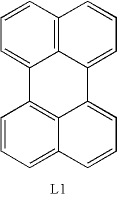

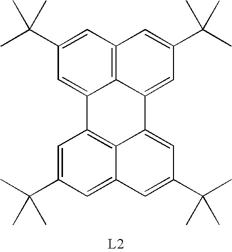

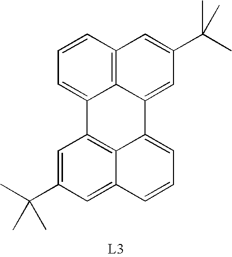

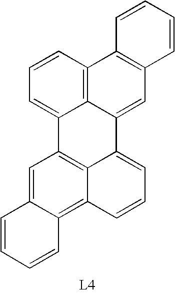

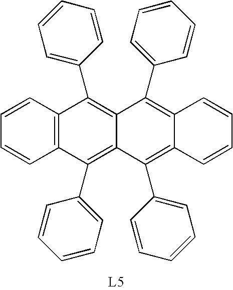

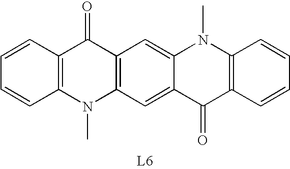

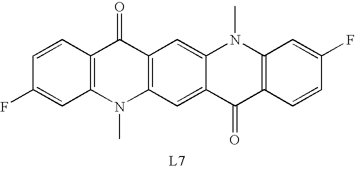

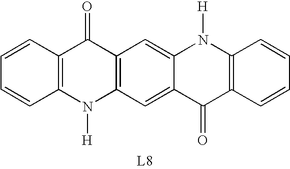

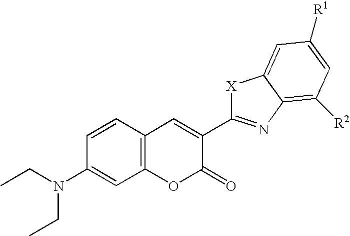

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

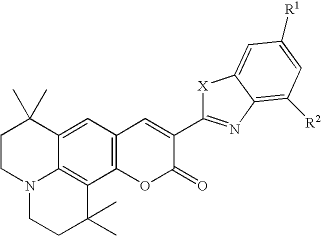

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | tbutyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyi | t-butyl |

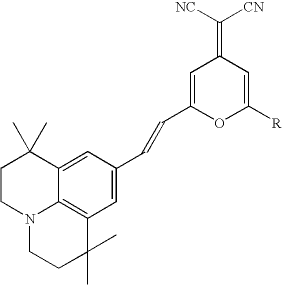

R

| | |
|---|---|
| L37 | phenyl |
| L38 | methyl |
| L39 | t-butyl |
| L40 | mesityl |

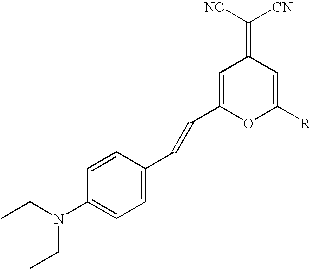

R

| | |
|---|---|
| L41 | phenyl |
| L42 | methyl |
| L43 | t-butyl |
| L44 | mesityl |

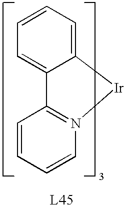

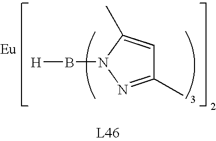

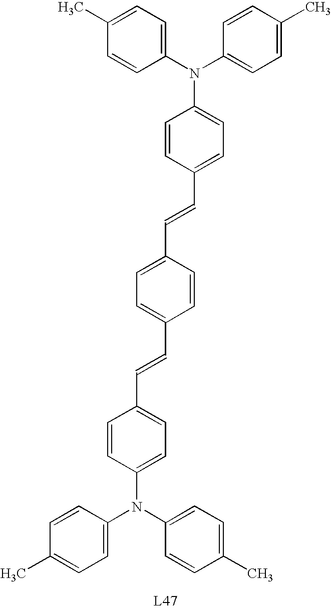

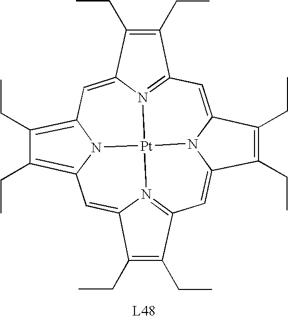

Many blue fluorescent dopants are known in the art, and are contemplated for use in the practice of this invention. Blue dopants or light-emitting materials can be coated as 0.01 to 50% by weight into the host material, but typically coated as 0.01 to 30 % and more typically coated as 0.01 to 15% by weight into the host material. The thickness of the blue-light emitting can be any suitable thickness. It can be in the range of from 10 to 100 nm. Particularly useful classes of blue-emitting dopants include perylene and its derivatives such as 2,5,8,11-tetra-tert-butyl perylene (TBP), and distyrylamine derivatives as described in U.S. Pat. No. 5,121,029, such as L47 (structure shown above)

Another useful class of blue-emitting dopants is represented by Formula 2, known as a bis(azinyloamine borane complex, and is described in commonly assigned U.S. Pat. No. 6,661,023 (Feb. 9, 2003) by Benjamin P. Hoag et al., entitled “Organic Element for Electroluminescent Devices”; the disclosure of which is incorporated herein. 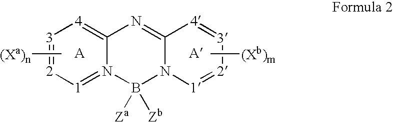
wherein:
A and A′ represent independent azine ring systems corresponding to 6-membered aromatic ring systems containing at least one nitrogen;
each X^{a} and X^{b} is an independently selected substituent, two of which may join to form a fused ring to A or A′;
m and n are independently 0 to 4;
Z^{a} and Z^{b} are independently selected substituents; and
1, 2, 3, 4, 1′, 2′, 3′, and 4′ are independently selected as either carbon or nitrogen atoms.

Desirably, the azine rings are either quinolinyl or isoquinolinyl rings such that 1, 2, 3, 4, 1′, 2′, 3′, and 4′ are all carbon; m and n are equal to or greater than 2; and X^{a} and X^{b} represent at least two carbon substituents which join to form an aromatic ring. Desirably, Z^{a} and Z^{b} are fluorine atoms.

Preferred embodiments further include devices where the two fused ring systems are quinoline or isoquinoline systems; the aryl or heterocyclic substituent is a phenyl group; there are present at least two X^{a} groups and two X^{b} groups which join to form a 6-6 fused ring, the fused ring systems are fused at the 1-2, 3-4, 1′-2′, or 3′-4′ positions, respectively; one or both of the fused rings is substituted by a phenyl group; and where the dopant is depicted in Formulae 3, 4, or 5. 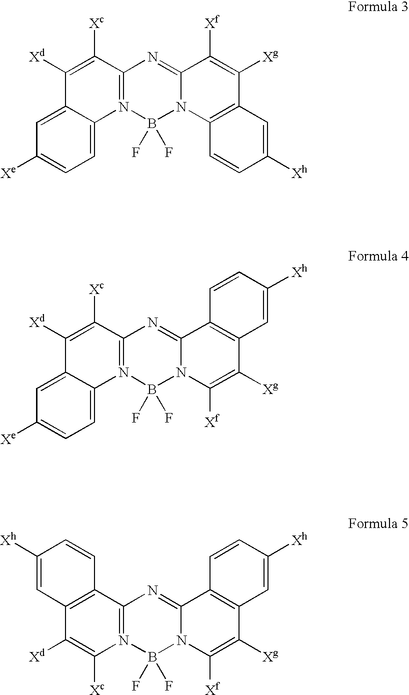
wherein each X^{c}, X^{d}, X^{e}, X^{f}, X^{g}, and X^{h} is hydrogen or an independently selected substituent, one of which must be an aryl or heterocyclic group.

Desirably, the azine rings are either quinolinyl or isoquinolinyl rings such that 1, 2, 3, 4, 1′, 2′, 3′, and 4′ are all carbon; m and n are equal to or greater than 2; and X^{a} and X^{b} represent at least two carbon substituents which join to form an aromatic ring, and one is an aryl or substituted aryl group. Desirably, Z^{a} and Z^{b} are fluorine atoms.

Illustrative, non-limiting examples of boron compounds complexed by two ring nitrogens of a deprotonated bis(azinyl)amine ligand, wherein the two ring nitrogens are members of different 6,6 fused ring systems in which at least one of the systems contains an aryl or heterocyclic substituent, useful in the present invention are the following:

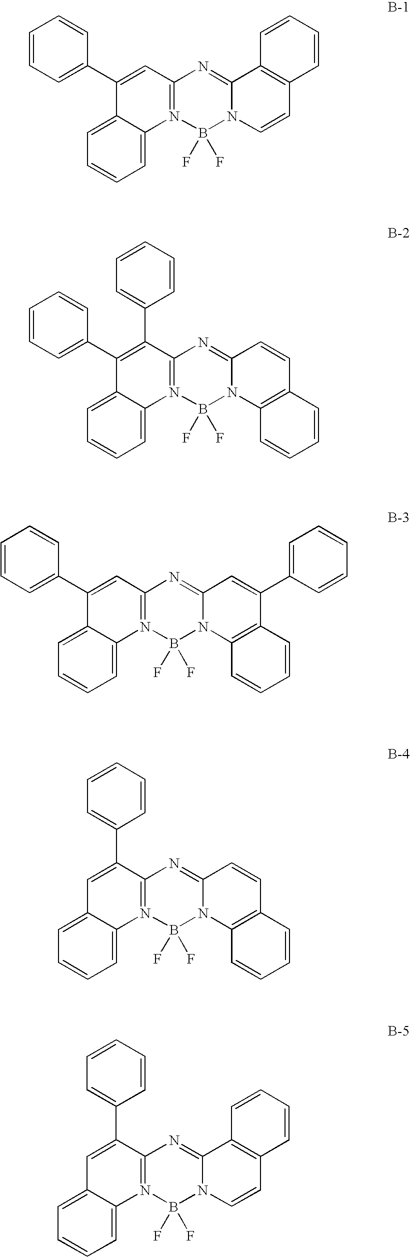

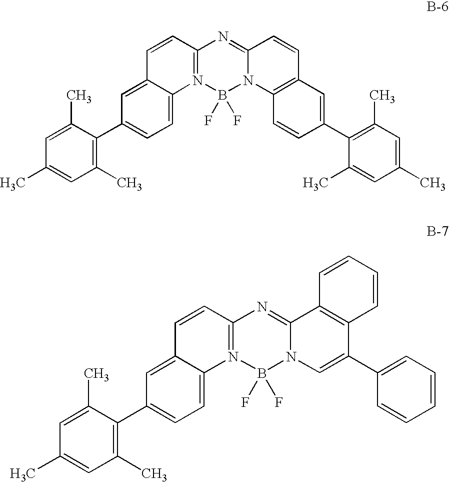

Coumarins represent a useful class of green-emitting dopants as described by Tang et al. in U.S. Pat. Nos. 4,769,292 and 6,020,078. Green dopants or light-emitting materials can be coated as 0.01 to 50% by weight into the host material, but typically coated as 0.01 to 30% and more typically coated as 0.01 to 15% by weight into the host material. Examples of useful green-emitting coumarins include C545T and C545TB. Quinacridones represent another useful class of green-emitting dopants. Useful quinacridones are described in U.S. Pat. No. 5,593,788, publication JP 09-13026A, and commonly assigned U.S. patent application Ser. No. 10/184,356 filed Jun. 27, 2002 by Lelia Cosimbescu, entitled “Device Containing Green Organic Light-Emitting Diode”, the disclosure of which is incorporated herein.

Examples of particularly useful green-emitting quinacridones are shown below:

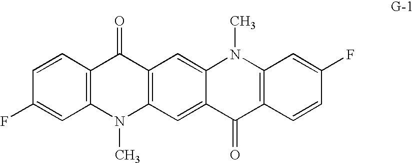

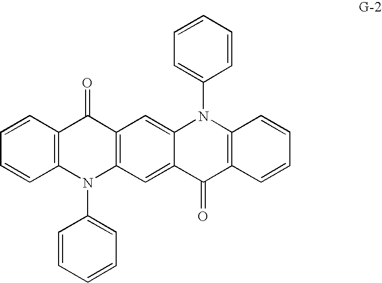

Formula 6 below represents another class of green-emitting dopants useful in the invention. 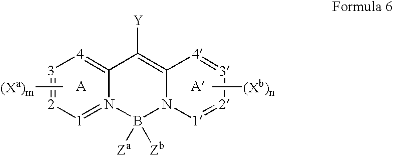
wherein:
A and A′ represent independent azine ring systems corresponding to 6-membered aromatic ring systems containing at least one nitrogen;
each X^{a} and X^{b} is an independently selected substituent, two of which may join to form a fused ring to A or A′;
m and n are independently 0 to 4;
Y is H or a substituent;
Z^{a} and Z^{b} are independently selected substituents; and
1, 2, 3, 4, 1′, 2′, 3′, and 4′ are independently selected as either carbon or nitrogen atoms.

In the device, 1, 2, 3, 4, 1′, 2′, 3′, and 4′ are conveniently all carbon atoms. The device may desirably contain at least one or both of ring A or A′ that contains substituents joined to form a fused ring. In one useful embodiment, there is present at least one X^{a} or X^{b} group selected from the group consisting of halide and alkyl, aryl, alkoxy, and aryloxy groups. In another embodiment, there is present a Z^{a} and Z^{b} group independently selected from the group consisting of fluorine and alkyl, aryl, alkoxy and aryloxy groups. A desirable embodiment is where Z^{a} and Z^{b} are F. Y is suitably hydrogen or a substituent such as an alkyl, aryl, or heterocyclic group.

The emission wavelength of these compounds may be adjusted to some extent by appropriate substitution around the central bis(azinyl)methene boron group to meet a color aim, namely green. Some examples of useful formulas follow:

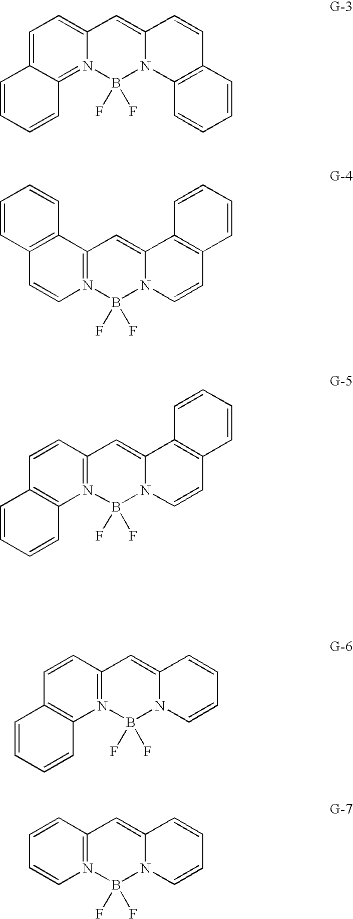

Naphthacenes and derivatives thereof also represent a useful class of emitting dopants, which can be used as stabilizers. These dopant materials can be coated as 0.01 to 50% by weight into the host material, but typically coated as 0.01 to 30% and more typically coated as 0.01 to 15% by weight into the host material. Naphthacene derivative Y-1 (alias t-BuDPN) below, is an example of a dopant material used as a stabilizer: 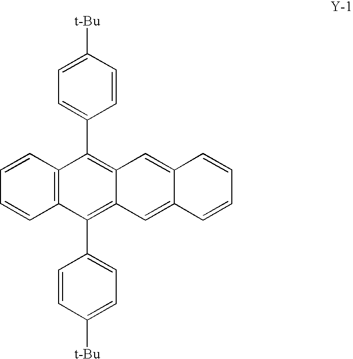
Electron-Transporting Layer (ETL)

Preferred thin film-forming materials for use in forming the electron-transporting layer 111 of the organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials.

In some instances, layers 109 and 111 can optionally be collapsed into a single layer that serves the function of supporting both light emission and electron transportation. The thickness of the ETL can be any suitable thickness. It can be in the range of from 0.1 nm to 100 nm.

Cathode

When light emission is through the anode, the cathode layer 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. Cathode materials are comprised of Mg:Ag, Al:Li and Mg:Al alloys. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in U.S. Pat. No. 5,677,572. Other useful cathode materials include, but are not limited to, those disclosed in U.S. Pat. No. 5,059,861, U.S. Pat. No. 5,059,862, and U.S. Pat. No. 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Deposition of Organic Layers

The organic materials mentioned above are suitably deposited through sublimation, but can be deposited from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,851,709 and U.S. Pat. No. 6,066,357) and inkjet method (U.S. Pat. No. 6,066,357).

Organic materials useful in making OLEDs, for example organic hole-transporting materials, organic light-emitting materials doped with an organic electroluminescent components have relatively complex molecular structures with relatively weak molecular bonding forces, so that care must be taken to avoid decomposition of the organic material(s) during physical vapor deposition. The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic material, the vapor condensing on a substrate to provide an organic layer thereon.

Several problems have been observed in using organic powders, flakes, or granules in physical vapor deposition: These powders, flakes, or granules are difficult to handle. These organic materials generally have a relatively low physical density and undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; This can lead to nonuniform heating of such organic materials in physical vapor deposition sources. Therefore, result in potentially nonuniform vapor-deposited organic layers formed on a substrate.

These organic powders can be consolidating into a solid pellet. These solid pellets consolidating into a solid pellet from a mixture of a sublimable organic material powder are easier to handle. Consolidation of organic powder into a solid pellet can be accomplished with relatively simple tools. A solid pellet formed from mixture comprising one or more non-luminescent organic non-electroluminescent component materials or luminescent electroluminescent component materials or mixture of non-electroluminescent component and electroluminescent component materials can be placed into a physical vapor deposition source for making organic layer. Such consolidated pellets can be used in a physical vapor deposition apparatus.

In one aspect, the present invention provides a method of making an organic layer from compacted pellets of organic materials on a substrate, which will form part of an OLED.

Encapsulation

Most OLED devices are sensitive to moisture and/or oxygen so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890.

Hole Blocking Layer

Some OLED devices require a Hole-Blocking Layer to either facilitate injection of electrons into the LEL or attenuate the passage of holes into the ETL to ensure recombination in the LEL (D. F. O'brien, M. A. Baldo, M. E. Thompson, and S. R. Forrest Appl. Phys. Lett. 74,442 (1999)). Typically this layer is thin (i.e., 10 nm) and it is located between the LEL and ETL.

Band Gap

An important relationship exists when selecting an electroluminescent compound. A comparison of the bandgap potential with respect to the bandgap(s) of the non-electroluminescent compound(s) in the LEL material must be carefully considered. In order for there to be efficient energy transfer from the non-electroluminescent compound to the electroluminescent component molecule, the band gap of the electroluminescent compound is typically smaller than that of the non-electroluminescent component material.

The bandgaps are typically determined experimentally by UVS or XPS spectroscopic techniques to characterize the energy levels and chemical nature of the HTL, LEL and ETL layers. All bandgaps as pertaining to this application are determined by the following procedure:
1. the absorption and emission spectra for a material are measured in a nonpolar solvent such as ethylacetate or toluene at low (i.e., <1×10⁻³ M) concentration and optical density (i.e., <0.2) bandgaps.
2. the spectra are normalized to one via the maximum absorption and emission bands in the visible region (i.e., 350-750 nm) of the spectrum.
3. the normalized absorption and emission spectra are plotted on the same chart.

4. the wavelength between the normalized absorption and emission spectra where they cross (crossing-wavelength) is defined as E_{0,0} and this “optical” bandgap otherwise known in the art as the energy difference between the highest occupied molecular orbital (HOMO) level or the maximum level of the valence band and the lowest unoccupied molecular orbital (LUMO) level or the minimum level of the conducting band. This value is typically reported in eV and that conversion is made by dividing the “crossing-wavelength” into 1240 eV nm.

Optical Bandgaps for Representative Materials

| Invention | Bandgap (eV) |
|---|---|
| Inv-1 | 2.12 eV |
| Inv-12 | 2.22 eV |
| Inv-19 | 2.31 eV |
| Inv-20 | 2.27 eV |
| Inv-21 | 2.28 eV |
| Inv-22 | 3.04 eV |
| Inv-23 | 2.51 eV |
| Inv-24 | 3.15 eV |
| Inv-27 | 2.76 eV |

The invention and its advantages are further illustrated by the specific examples that follow. The term “percentage” or “percent” and the symbol “%” indicate the volume percent (or a thickness ratio as measured on a thin film thickness monitor) of a particular electroluminescent or non-electroluminescent compound of the total material in the light-emitting layer. If more than one electroluminescent or non-electroluminescent compound is present the total volume of the electroluminescent or non-electroluminescent compounds can also be expressed as a percentage of the total material in the light-emitting layer. Volume percent can be converted to weight percent by employing the equation d=m/v, which gives the relationship between density d, mass m, and volume v.

The entire contents of the patents and other publications referred to in this specification are incorporated herein by reference.

### EXAMPLES

The inventions and its advantages are further illustrated by the specific examples, which follow.

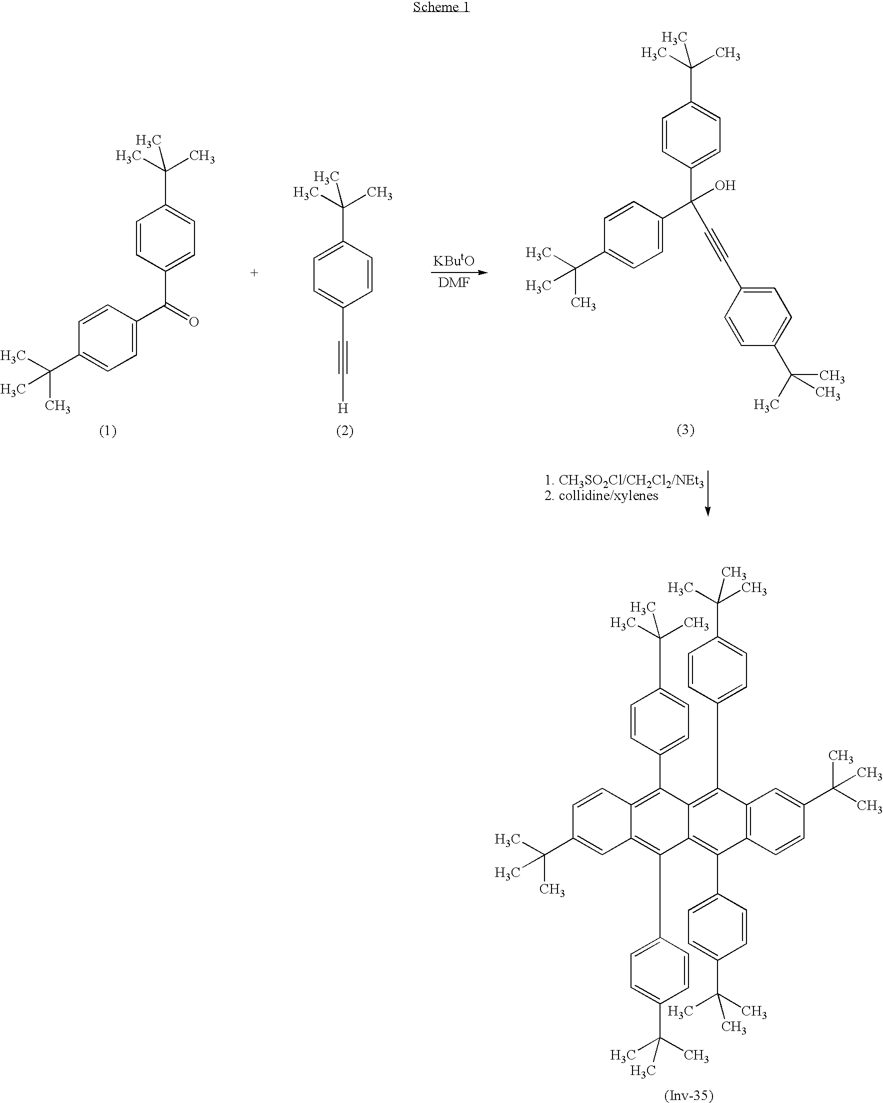

### Example 1

### Synthesis (Scheme 1)

Preparation of compound (3): Under a nitrogen atmosphere, acetylenic compound (2) (2.0g, 12mMole), was dissolved in dimethylformamide (DMF) (100mL) and the solution cool to 0° C. Potassium t-butoxide (KBu^{t}O) (1.4 g, 12mMole), was added and the mixture stirred well for approximately 15 minutes. To this mixture was then added the benzophenone (1) (3.53 g, 30mMole). Stirring was continued at 0° C. for approximately 30 minutes and then allowed to come to room temperature over a 1-hour period. At the end of this time the solution was cooled to 0° C. and the reaction treated with saturated sodium chloride (20mL). The mixture was then diluted with ethyl acetate, washed with 2N-HCl (×3), dried over MgSO₄, filtered and concentrated under reduced pressure. The crude product was triturated with petroleum ether to give the product as an off-white solid. Yield of compound (3), 3.0 g.

Preparation of Inventive Compound, Inv-35: Compound (3) (7.0 g, 15mMole) was dissolved in methylene chloride (CH₂Cl₂) (70mL), and stirred at 0° C. under a nitrogen atmosphere. To this solution was added triethylamine (NEt₃) (1.56 g, 15mMole) and then treated drop by drop with methanesulfonyl chloride (CH₃SO₂Cl) (1.92 g, 15mMole), keeping the temperature of the reaction in the range 0-5° C. After the addition the solution was stirred at 0° C. for 30 minutes and then allowed to warm to room temperature over 1 hour. The reaction was then heated to reflux, distilling off the methylene chloride solvent and gradually replacing it with xylenes (a total of 70mL). When the internal temperature of the reaction reached 80° C., collidine (2.40 g, 19.82mMole), dissolved in xylenes (10mL) was added drop by drop over a 10-minute period. The temperature was then raised to 110° C. and held at this temperature for 4 hours. After this period the reaction was cooled and concentrated under reduced pressure. The oily residue was stirred with methanol (70mL) to give the crude product. This material was filtered off, washed with methanol and petroleum ether to give inventive compound Inv-35 as a bright red solid. Yield 1.5 g with a melting point of 300-305° C. The product may be further purified by sublimation (250° C.@200 millitorr) with a N₂ carrier gas.

The comparative compounds used in the invention are as follows:

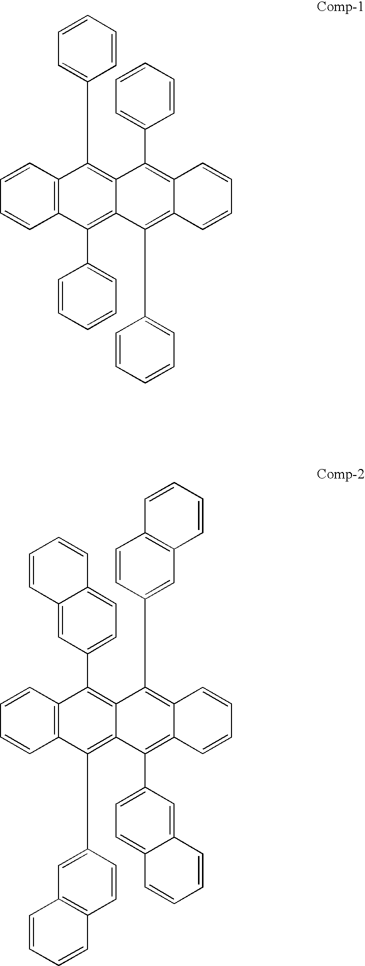

Comp-1 is the parent rubrene and falls outside the scope of the current invention. It is well known to those in the art and has no substituents at the 2- and 8-positions on either of the end rings of the naphthacene nucleus, nor on the four phenyl rings located on the center rings of the naphthacene. It is found as the host in Example 3 of U.S. Pat. No. 6,613,454. Comp-2, 5,6,11,12-tetra-(2′-naphthalenyl)naphthacene (NR), also falls outside the scope of the current invention. It has four 2-naphthyl groups in the 5-, 6-, 11- and 12-positions of the naphthacene nucleus, has no substituents at the 2- and 8-positions and is compound IB-81 in U.S. Pat. No. 6,613,454. In the following Examples 2, 3 and 4, Inv-1 and Inv-9 are electroluminescent compounds with the first bandgap, ELC-1. Inv-35 and Inv-36 are non-electroluminescent compounds with the second bandgap, non-ELC-2. Inv-27 and Inv-24 are non-electroluminescent compounds with the further bandgap, non-ELC-3. Comp-1 and Comp-2 are comparison compounds and are also non-electroluminescent compounds with second bandgaps, non-ELC-2.

### Example 2

### EL Device Fabrication—Inventive And Comparative Examples

An EL device satisfying the requirements of the invention was constructed as Sample 1 in the following manner:

A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.
a) Over the ITO was deposited a 1 nm fluorocarbon (CFₓ) hole-injecting layer (HIL) by plasma-assisted deposition of CHF₃.
b) A hole-transporting layer (HTL) of N,N′-di-1-naphthalenyl-N,N′-diphenyl-4,4′-diaminobiphenyl (NPB, Inv-24) having a thickness of 150 nm was then evaporated onto a).
c) A 37.5 nm light-emitting layer (LEL) of the non-ELCs, tris(8-quinolinolato)aluminum (III) (AlQ₃, Inv-27) and Inv-36, and the ELC, Inv-1 (see Tables 1 and 2 for concentration expressed as %) were then deposited onto the hole-transporting layer.
d) A 37.5 nm electron-transporting layer (ETL) of tris(8-quinolinolato)aluminum (III) (AlQ₃, Inv-27) was then deposited onto the light-emitting layer.
e) On top of the AlQ₃ layer was deposited a 220 nm cathode formed of a 10:1 volume ratio of Mg and Ag.

The above sequence completed the deposition of the EL device. The device was then hermetically packaged in a dry glove box for protection against ambient environment.

The results for Example 2 are recorded in Tables 1, 2, 3 and 4 as Samples 1- 6.

Samples 2 and 3 of Tables 1 and 2 are comparison EL devices, fabricated in an identical manner to Sample 1, but incorporating comparison compounds Comp-1 and Comp-2 respectively, in place of Inv-36 and at the same nominal levels as Inv-36.

Sample 4 of Tables 3 and 4 is the EL device of the invention incorporating ELC Inv-9, with non-ELCs Inv-35 and Inv-27 and fabricated in an identical manner to Sample 1.

Sample 5 of Tables 3 and 4 is the EL device of the invention incorporating ELC Inv-9, with non-ELCs Inv-36 and Inv-27, and fabricated in an identical manner to Sample 1.

Sample 6 of Tables 3 and 4 is a comparison EL device incorporating ELC Inv-9, with non-ELCs Comp-2 and Inv-27, and fabricated in an identical manner to Sample 1.

Tables 1 and 3 refer to the luminance behavior of the samples while Tables 2 and 4 refer to the stability behavior of the samples.

### Example 3

### EL Device Fabrication—Inventive And Control Samples

A white EL device satisfying the requirements of the invention was constructed as Samples 7 through Sample 12 in the following manner:

A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.
a) Over the ITO was deposited a 1 nm fluorocarbon (CFx) hole-injecting layer (HIL) by plasma-assisted deposition of CHF₃.
b) A hole-transporting layer (HTL) of N,N′-di-1-naphthalenyl-N,N′-diphenyl-4,4′-diaminobiphenyl (NPB, Inv-24) having a thickness of 140 nm was then evaporated onto a).
c) A second layer having a thickness of 30 nm and comprising electroluminescent compound Inv-1 with the first bandgap, non-electroluminescent compound Inv-36 with the second bandgap and non-electroluminescent compound Inv-24 with the further bandgap comprising the concentrations as recorded in Example 3, red electroluminescent component of Table 5, were then deposited onto layer b).
d) A 45 mn blue light-emitting layer (LEL) comprising electroluminescent compound Inv-44, non-electroluminescent compound Inv-28 and non-electroluminescent compound Inv-24 in the concentrations as recorded in Example 3, blue electroluminescent component of Table 5, were then deposited onto layer c).
e) A 10 nm electron-transporting layer (ETL) of tris(8-quinolinolato)aluminum (III) (AlQ₃) was then deposited onto d).
f) On top of the ETL-AlQ₃ layer was deposited a 5 nm layer of lithium fluoride; and
g) On top of the lithium fluoride layer was then deposited 200 nm of aluminium to complete the cathode.

The above sequence completed the deposition of the white EL device. The device was then hermetically packaged in a dry glove box for protection against ambient environment.

### Example 4

### EL Device Fabrication—Inventive And Control Samples

A white EL device satisfying the requirements of the invention was constructed as Samples 13 through Sample 17 in the same manner as Example 3 except that the electroluminescent compound of the blue component in paragraph d) was replaced with Inv-43.

TABLE 1
Evaluation Results for EL devices Containing Electroluminescent
Compound, Inv-1 and Non-Electroluminescent Compounds.

| | | ELC-1 | Non-ELC-2 | Non-ELC-3 | Yield |
|---|---|---|---|---|---|
| Sample | Type | % | % | % | (cd/A)¹ |
| 1 | Inventive | Inv-1 | Inv-36 | Inv-27 | |
| | | 0.5 | 5 | 94.5 | 4.39 |
| | | | 10 | 89.5 | 4.12 |
| | | | 25 | 74.5 | 4.24 |
| 2 | Comparative | Inv-1 | Comp-1 | Inv-27 | |
| | | 0.5 | 5 | 94.5 | 3.14 |
| | | | 10 | 89.5 | 3.44 |
| | | | 25 | 74.5 | 4.61 |
| 3 | Comparative | Inv-1 | Comp-2 | Inv-27 | |
| | | 0.5 | 5 | 94.5 | 2.09 |
| | | | 10 | 89.5 | 2.42 |
| | | | 25 | 74.5 | 3.22 |

¹Luminance yields and efficiencies reported at 20 mA/cm².

TABLE 2
Stability Results for EL devices Containing Electroluminescent
Compound, Inv-1 and Non-Electroluminescent Compounds.

| | | ELC-1 | Non-ELC-2 | Non-ELC-3 | |
|---|---|---|---|---|---|
| Sample | Type | % | % | % | Stability² |
| 1 | Inventive | Inv-1 | Inv-36 | Inv-27 | |
| | | 0.5 | 5 | 94.5 | 96 |
| | | | 10 | 89.5 | 97 |
| | | | 25 | 74.5 | 95 |
| 2 | Comparative | Inv-1 | Comp-1 | Inv-27 | |
| | | 0.5 | 5 | 94.5 | 93 |
| | | | 10 | 89.5 | 92 |
| | | | 25 | 74.5 | 88 |

²Stability refers to the % of luminance remaining after the device has operated for 200 hours at 70° C. with a current density of 20 mA/cm².

TABLE 3
Evaluation Results for EL devices Containing Electroluminescent
Compound, Inv-9 and Non-Electroluminescent Compounds.

| | | ELC-1 | Non-ELC-2 | Non-ELC-3 | Yield |
|---|---|---|---|---|---|
| Sample | Type | % | % | % | (cd/A)¹ |
| 4 | Inventive | Inv-9 | Inv-35 | Inv-27 | |
| | | 0.5 | 5 | 94.5 | 4.18 |
| | | | 10 | 89.5 | 3.79 |
| | | | 25 | 74.5 | 3.37 |
| | | | 50 | 49.5 | 2.97 |
| | | | 75 | 24.5 | 2.57 |
| 5 | Inventive | Inv-9 | Inv-36 | Inv-27 | |
| | | 0.5 | 5 | 94.5 | 4.30 |
| | | | 10 | 89.5 | 3.75 |
| | | | 25 | 74.5 | 3.33 |
| | | | 50 | 49.5 | 2.74 |
| | | | 75 | 24.5 | 2.26 |
| 6 | Comparative | Inv-9 | Comp-2 | Inv-27 | |
| | | 0.5 | 5 | 94.5 | 2.38 |
| | | | 10 | 89.5 | 2.45 |
| | | | 25 | 74.5 | 2.73 |
| | | | 50 | 49.5 | 2.59 |
| | | | 75 | 24.5 | 2.62 |

¹Luminance yields and efficiencies reported at 20 mA/cm².

TABLE 4
Stability Results for EL devices Containing Electroluminescent
Compound, Inv-9 and Non-Electroluminescent Compounds.

| | | ELC-1 | Non-ELC-2 | Non-ELC-3 | |
|---|---|---|---|---|---|
| Sample | Type | % | % | % | Stability² |
| 4 | Inventive | Inv-9 | Inv-35 | Inv-27 | |
| | | 0.5 | 5 | 94.5 | 65 |
| | | | 10 | 89.5 | 63 |
| 5 | Inventive | Inv-9 | Inv-36 | Inv-27 | |
| | | 0.5 | 5 | 94.5 | 61 |
| | | | 10 | 89.5 | 62 |
| 6 | Comparative | Inv-9 | Comp-2 | Inv-27 | |
| | | 0.5 | 5 | 94.5 | 55 |
| | | | 10 | 89.5 | 57 |

²Stability refers to the % of luminance remaining after the device has operated for 200 hours at 70° C. with a current density of 20 mA/cm².

TABLE 5
Examples 3 and 4: Luminance Yields and CIE Color Coordinates for Red Component of White EL Devices.

| | | | | | | | Luminance | CIE Color | |
|---|---|---|---|---|---|---|---|---|---|
| | Red Electroluminescent Component | | | Blue Electroluminescent Component | | | Yield (cd/A) | Co-ordinates³ | |
| Sample | ELC-1 (%) | Non-ELC-2 (%) | Non-ELC-3 (%) | ELC-1 (%) | Non-ELC-2 (%) | Non-ELC-3 (%) | Red Filter³ | CIEₓ | CIE_{y} |
| Example 3 | | | | | | | | | |
| 7 | Inv-1 (0.5) | Inv-36 (0) | Inv-24 (99.5) | Inv-44 (2.5) | Inv-28 (91) | Inv-24 (6.5) | 1.61 | 0.652 | 0.344 |
| 8 | Inv-1 (0.5) | Inv-36 (5) | Inv-24 (94.5) | Inv-44 (2.5) | Inv-28 (91) | Inv-24 (6.5) | 2.89 | 0.652 | 0.346 |
| 9 | Inv-1 (0.5) | Inv-36 (20) | Inv-24 (79.5) | Inv-44 (2.5) | Inv-28 (91) | Inv-24 (6.5) | 3.37 | 0.657 | 0.341 |
| 10 | Inv-1 (0.5) | Inv-36 (50) | Inv-24 (49.5) | Inv-44 (2.5) | Inv-28 (91) | Inv-24 (6.5) | 3.60 | 0.656 | 0.343 |
| 11 | Inv-1 (0.5) | Inv-36 (75) | Inv-24 (24.5) | Inv-44 (2.5) | Inv-28 (91) | Inv-24 (6.5) | 3.39 | 0.655 | 0.344 |
| 12 | Inv-1 (0.5) | Inv-36 (90) | Inv-24 (9.5) | Inv-44 (2.5) | Inv-28 (91) | Inv-24 (6.5) | 3.29 | 0.653 | 0.345 |
| Example 4 | | | | | | | | | |
| 13 | Inv-1 (0.5) | Inv-36 (0) | Inv-24 (99.5) | Inv-43 (2.5) | Inv-28 (91) | Inv-24 (6.5) | 1.03 | 0.652 | 0.334 |
| 14 | Inv-1 (0.5) | Inv-36 (5) | Inv-24 (94.5) | Inv-43 (2.5) | Inv-28 (91) | Inv-24 (6.5) | 2.67 | 0.653 | 0.344 |
| 15 | Inv-1 (0.5) | Inv-36 (20) | Inv-24 (79.5) | Inv-43 (2.5) | Inv-28 (91) | Inv-24 (6.5) | 3.44 | 0.658 | 0.339 |
| 16 | Inv-1 (0.5) | Inv-36 (50) | Inv-24 (49.5) | Inv-43 (2.5) | Inv-28 (91) | Inv-24 (6.5) | 3.66 | 0.657 | 0.341 |
| 17 | Inv-1 (0.5) | Inv-36 (75) | Inv-24 (24.5) | Inv-43 (2.5) | Inv-28 (91) | Inv-24 (6.5) | 3.47 | 0.655 | 0.343 |

³The luminance yield and CIE color co-ordinates were determined after passing the white light from the OLED device through a red filter having the following characteristics, (transmittance, wavelength): (0%, 570 nm); (13%, 580 nm); (57%, 590); (72%, 600 nm); (78%, 610); (80%, 620-640 nm); (88%, 650 nm); and (92%, 660-700 nm).

As can be seen from Tables 1 and 3, the EL devices of the invention Samples 1, 4 and 5 consistently show superior luminance over the comparison EL devices of Samples 2, 3 and 6, at all coated levels of the electroluminescent and non-electroluminescent compounds. In addition, Tables 2 and 4 show that the operational stability of the EL devices of the invention are also consistently superior to those of the comparison EL devices.

Example 3 is an OLED device producing white light using the red light component of the invention incorporating electroluminescent compound Inv-1 with the first bandgap, non-electroluminescent compound Inv-36 with the second bandgap and non-electroluminescent compound Inv-24 with the further bandgap. The blue component comprises Inv-44, Inv-28 and Inv-24. Sample 7 is the control for Example 3 incorporating 0% of non-electroluminescent compound Inv-36 with the second bandgap.

Example 4 is another OLED device producing white light and is similar to Example 3. The red light component of the invention again incorporates electroluminescent compound Inv-1 with the first bandgap, non-electroluminescent compound Inv-36 with the second bandgap and non-electroluminescent compound Inv-24 with the further bandgap. The blue component comprises Inv-43, Inv-28 and Inv-24. Sample 13 is the control for Example 4 incorporating 0% of non-electroluminescent compound Inv-36 with the second bandgap.

The white light from Samples 7 through 17 was passed through a red filter having the following transmittance characteristics, (transmittance, wavelength): (0%, 570 nm); (13%, 580 nm); (57%, 590); (72%, 600 nm); (78%, 610); (80%, 620-640 nm); (88%, 650 nm); and (92%, 660-700 nm); and the luminance yields and CIE color co-ordinates recorded. It can be seen from Table 5, Samples 7 through 17, that while the red CIE color co-ordinates obtained by passing the light through the color filter are essentially the same, the luminance yield increases as the level of non-electroluminescent compound Inv-36 with the second bandgap, increases. Control Samples 7 and 13, with 0% of non-electroluminescent compound Inv-36 with the second bandgap, show the lowest luminance yields.

The invention has been described in detail with particular reference to certain preferred embodiments thereof, but it will be understood that variations and modifications can be effected within the spirit and scope of the invention. For example, multiple electroluminescent compounds and multiple non-electroluminescent compounds can be used in any of the hole-transporting, electron-transporting or light-emitting layers.

The patents and other publications referred to are incorporated herein in their entirety.

### PARTS LIST

101 Substrate
103 Anode
105 Hole-Injecting layer (HIL)
106 First Hole-Transporting layer (HTL-1)
107 Hole-Transporting layer (HTL-1)
108 Second Hole-Transporting layer (HTL-2)
109 Light-Emitting layer (LEL)
110 First Electron-Transporting layer (ETL-1)
111 Electron-Transporting layer (ETL-1)
112 Second Electron-Transporting layer (ETL-2)
112b Third Electron-Transporting layer (ETL-3)
113 Cathode

1. An OLED device that produces white light comprising (A) a red light emitting layer and (B) a blue light emitting layer wherein said red light emitting layer contains an electroluminescent component having a first bandgap, a non-electroluminescent component having a second bandgap, and one or more further non-electroluminescent components having further bandgaps, wherein:
i) the second bandgap is equal to or greater than the first bandgap but is not more than 2.7 eV;
ii) each of the one or more further bandgaps is greater than the first and second bandgaps;
iii) the non-electroluminescent componene with the second bandgap is present in an amount of 0.1 to 99.8 vol. percent of the total material in the red light emitting layer;
iv) the one or more non-electroluminescent components with further bandgaps are present in a combined amount of 0.1 to 99.8 vol. percent of the total material in the red light emitting layer;
v) the electroluminescent component is present in an amount of 0.1 to 5 vol. percent of the total material in the light emitting layer; and
vi) the non-electroluminescent component with the second bandgap is represented by formula (Ia); 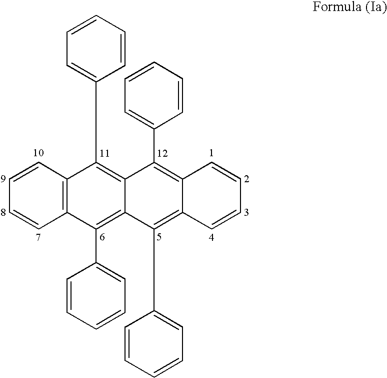
wherein:
a) any hydrogen on the phenyl rings in the 6- and 12-positions may be substituted;
b) there are identical substituent groups at the 2- and 8-positions; and
c) the phenyl rings in the 5- and 11-positions contain only para-substituents identical to the substituent groups in paragraph b).

2. The OLED of claim 1 wherein the electroluminescent component of the red emitting layer with the first bandgap is a periflanthene compound represented by formula (II): 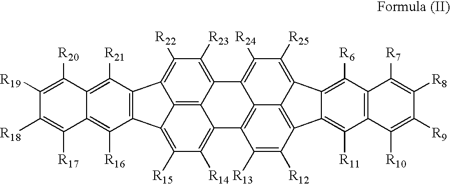
wherein:
R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄, R₂₅ are independently selected as hydrogen or substituents;
provided that any of the R₆ through R₂₅ substituents may join to form further fused rings.

3. The OLED of claim 2 wherein at least one R₆, R₇, R₈, R₉, R₁₀, R₁₁, R₁₂, R₁₃, R₁₄, R₁₅, R₁₆, R₁₇, R₁₈, R₁₉, R₂₀, R₂₁, R₂₂, R₂₃, R₂₄ and R₂₅ are independently selected from the group consisting of halide, alkyl, aryl, alkoxy and aryloxy groups.

4. The OLED of claim 3 wherein at least one substituent is a phenyl group.

5. The OLED of claim 1 wherein the non-electroluminescent component in the red light emitting layer with the second bandgap is represented by formula (Ib); 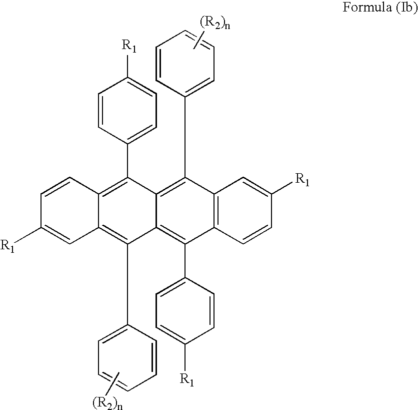
wherein
R₁ and R₂ are substituent groups;
n is 1-5;
provided that the R₁ groups are the same; and
provided further, that the R₂ groups, their location and n value on one ring are the same as those on the second ring.

6. The OLED of claim 5 wherein R₁ is represented by the formula; 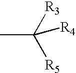
wherein each of R₃, R₄ and R₅ is hydrogen or an independently selected substituent or R₃, R₄ and R₅ taken together can form a mono- or multi-cyclic ring system.

7. The OLED of claim 2 wherein the non-electroluminescent component in the red light emitting layer with the second bandgap is in the range of 5 to 95 vol. percent of the total material in the light emitting layer.

8. The OLED of claim 2 wherein the non-electroluminescent component in the red light emitting layer with the second bandgap is in the range of 10 to 75 vol. percent of the total material in the light emitting layer.

9. The OLED of claim 2 wherein the periflanthene compound is represented by one of the following formulae:

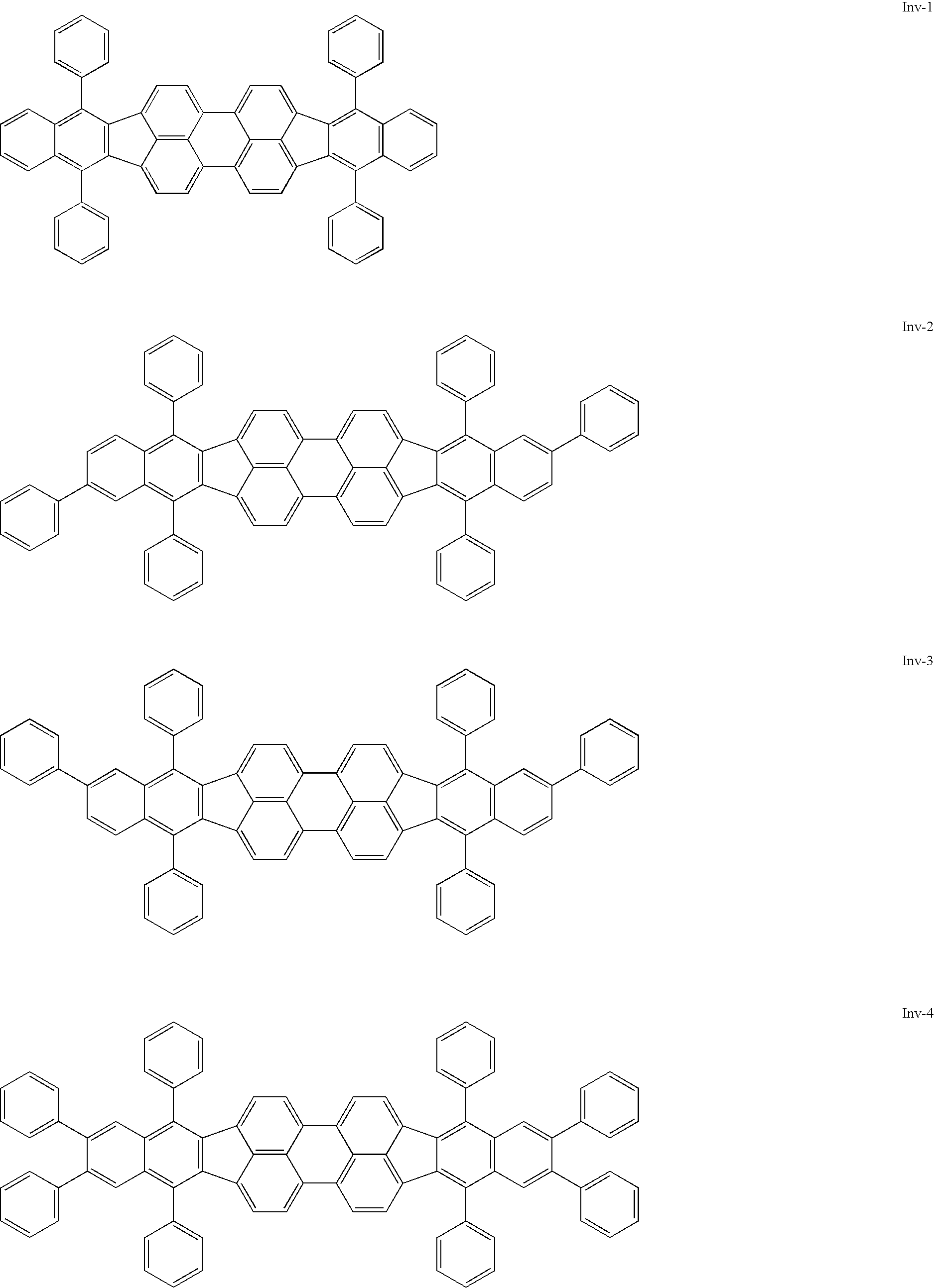

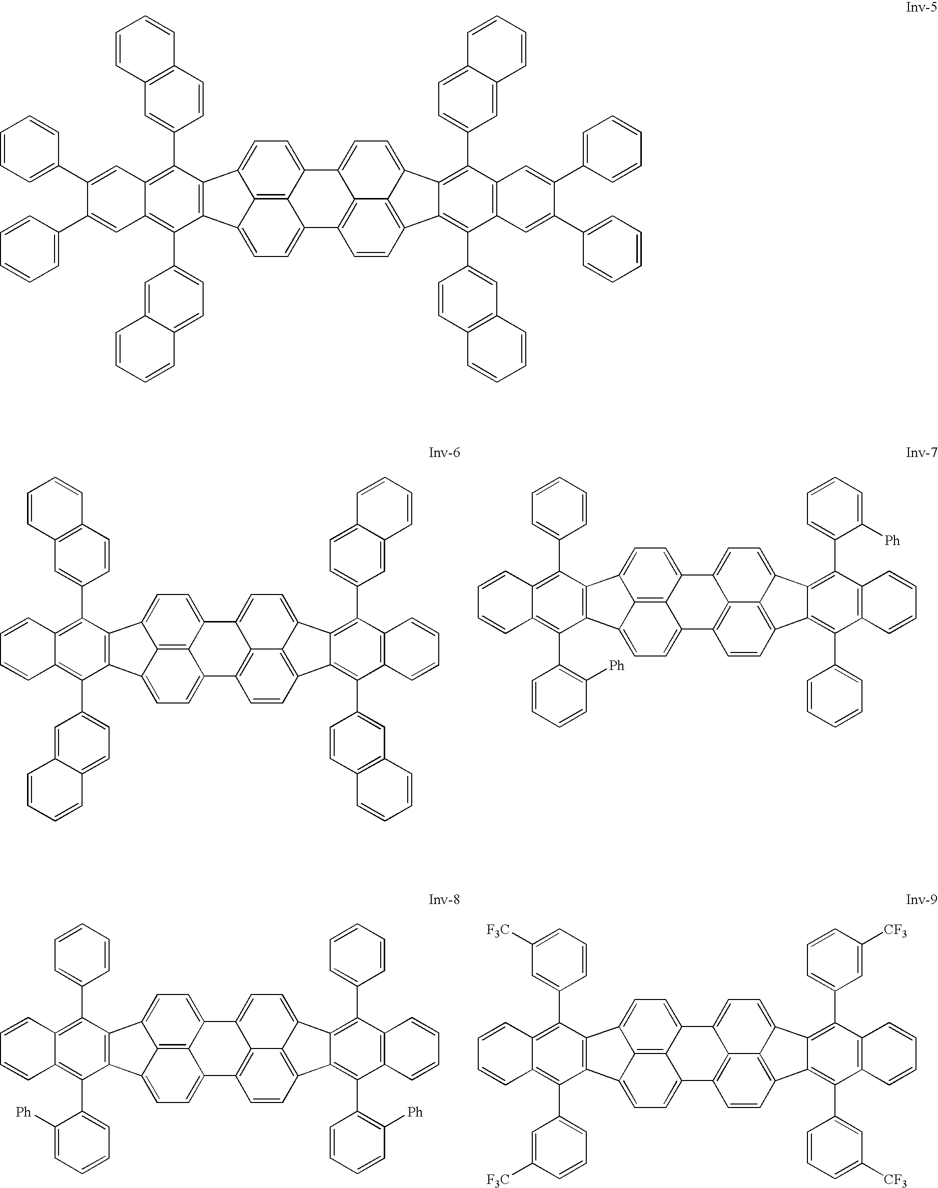

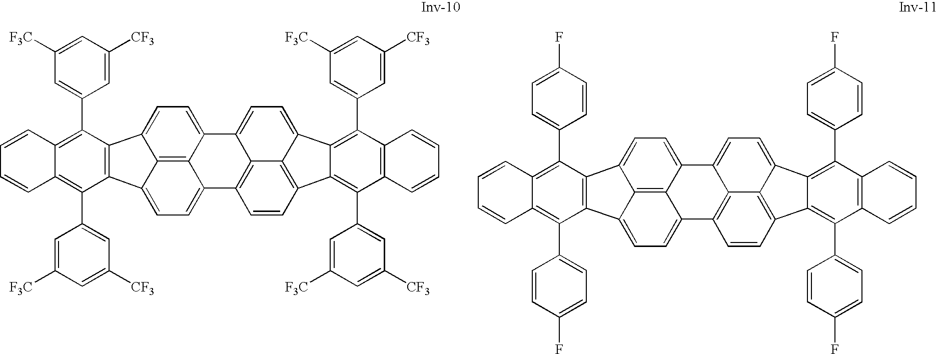

10. The OLED of claim 2 wherein the electroluminescent component in the red light emitting layer with the first bandgap is in the range of 0.1 to 5 vol. percent of the total material in the light emitting layer.

11. The OLED of claim 2 wherein the electroluminescent component in the red light emitting layer with the first bandgap is in the range of 0.3 to 1.5 vol. percent of the total material in the light emitting layer.

12. The OLED of claim 1 wherein the electroluminescent component in the red light emitting layer with the first bandgap is a pyran derivative represented by formula (III): 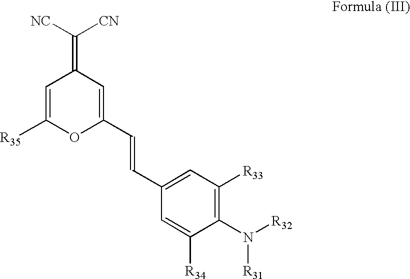
wherein:
R₃₁, R₃₂, R₃₃, R₃₄, and R₃₅ are independently selected as hydrogen or substituents;
provided that any of the indicated substituents may join to form further fused rings.

13. The OLED of claim 12 wherein R₃₁, R₃₂, R₃₃, R₃₄, and R₃₅ are selected independently from the group consisting of hydrogen, alkyl and aryl groups.

14. The OLED of claim 12 wherein at least one of R₃₁, R₃₂, R₃₃, R₃₄, and R₃₅ is independently selected from the group consisting of halide, alkyl, aryl, alkoxy and aryloxy groups.

15. The OLED of claim 12 wherein the non-electroluminescent component in the red light emitting layer with the second bandgap is in the range of 5 to 95 vol. percent of the total material in the light emitting layer.

16. The OLED of claim 12 wherein the non-electroluminescent component in the red light emitting layer with the second bandgap is in the range of 10 to 75 vol. percent of the total material in the light emitting layer.

17. The OLED device of claim 12 wherein the compound of formula (III) is represented by one of the following formulae:

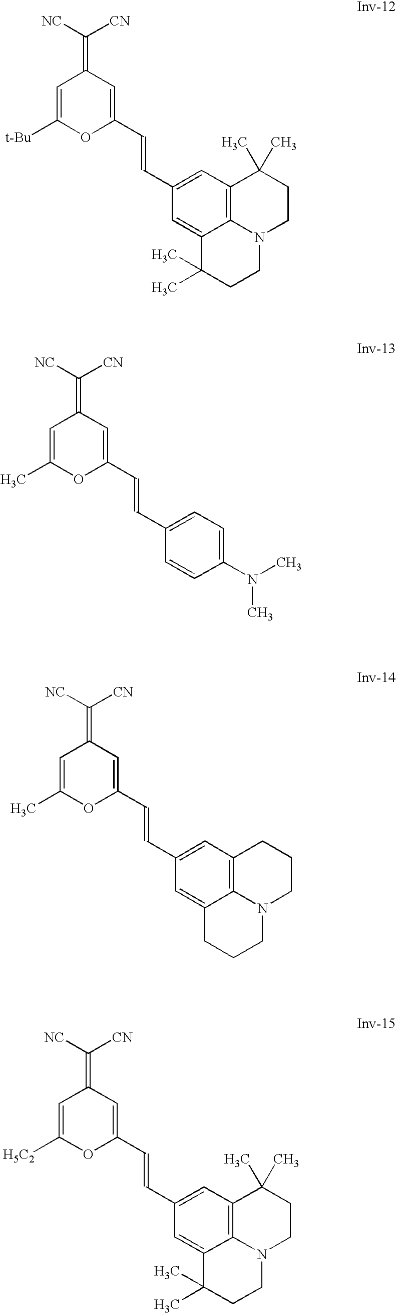

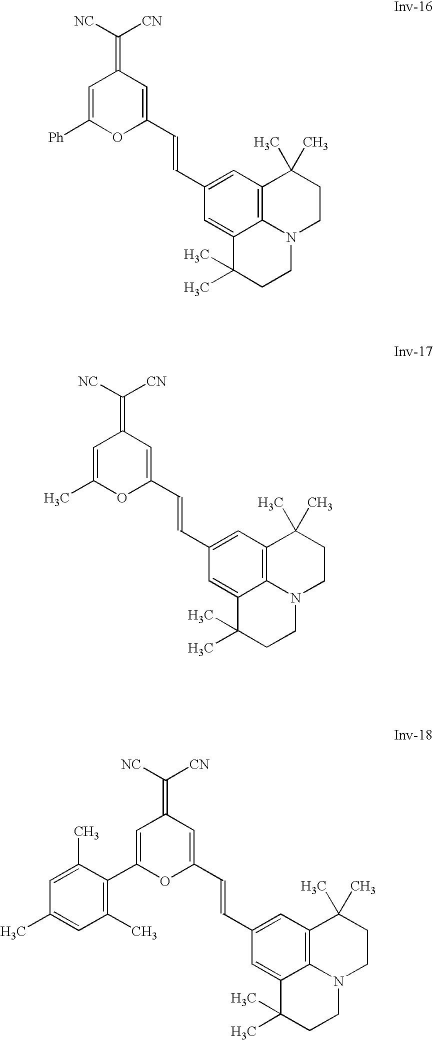

18. The OLED of claim 12 wherein the electroluminescent compound in the red light emitting layer with the first bandgap is in the range from 0.1 to 5 vol. percent of the total material in the light emitting layer.

19. The OLED of claim 12 wherein the electroluminescent component in the red light emitting layer with the first bandgap is in the range from 0.5 to 1.5 vol. percent of the total material in the light emitting layer.

20. The OLED of claim 6 wherein R₃, R₄, and R₅ are selected from alkyl groups.

21. The OLED of claim 6 wherein R₃, R₄, and R₅ are methyl groups.

22. The OLED of claim 1 wherein the non-electroluminescent component in the red light emitting layer with the second bandgap is represented by one of the following formulae;

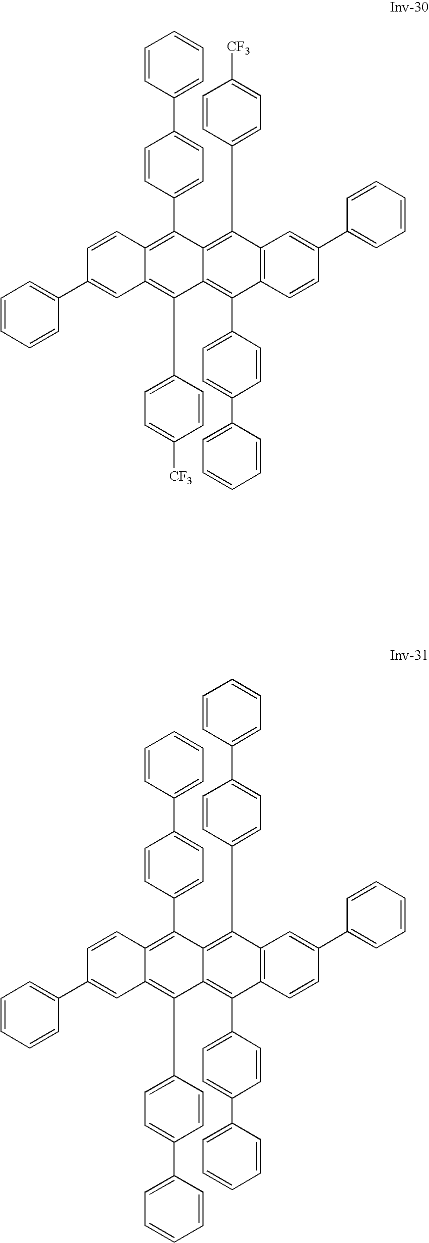

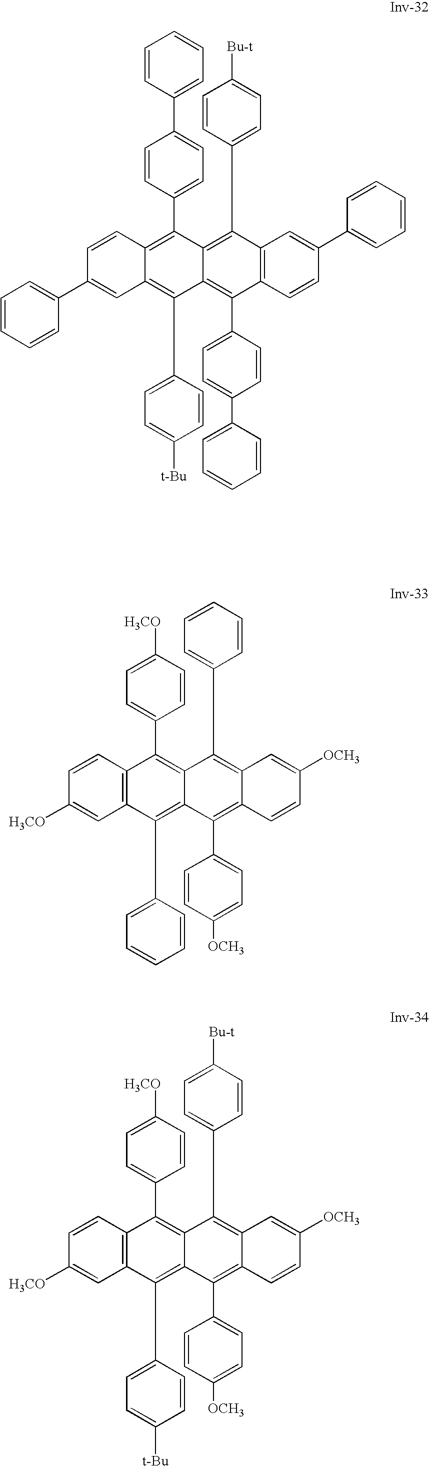

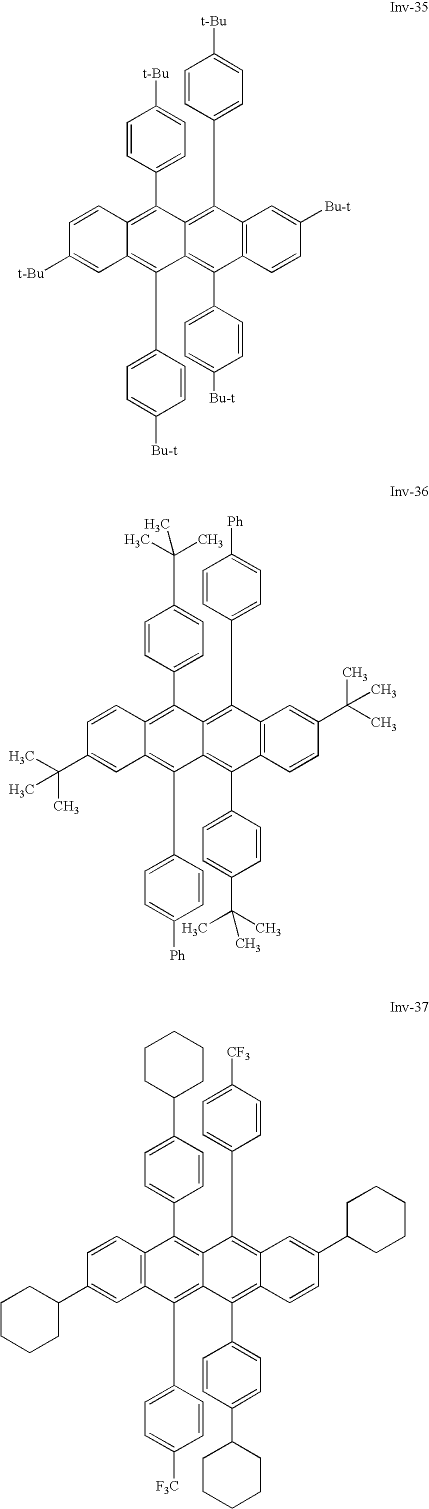

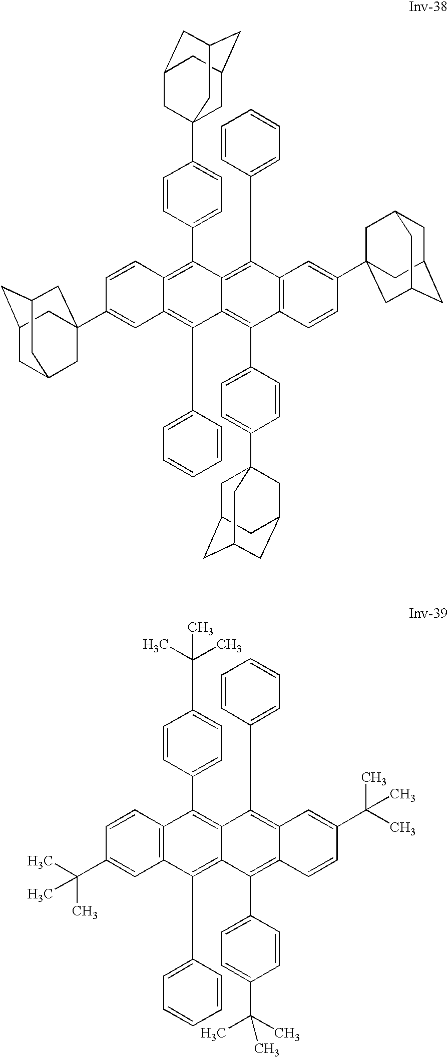

23. The OLED device of claim 1 wherein the non-electroluminescent component in the red light emitting layer with a further bandgap is represented by formula (IV): 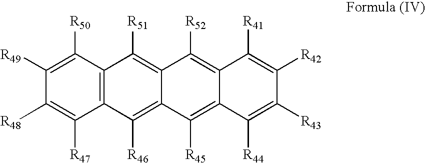
wherein:
R₄₁, R₄₂, R₄₃, R₄₄, R₄₅, R₄₆, R₄₇, R₄₈, R₄₉, R₅₀, R₅₁, and R₅₂ are independently selected as hydrogen or substituents;
provided that any of the indicated substituents may join to form further fused rings.

24. The OLED device of claim 23 wherein at least one of R₄₁, R₄₂, R₄₃, R₄₄, R₄₅, R₄₆, R₄₇, R₄₈, R₄₉, R₅o, R₅₁, and R₅₂ are independently selected from the group consisting of halide, alkyl, aryl, alkoxy and aryloxy groups.

25. The OLED device of claim 1 wherein a non-electroluminescent component in the red light emitting layer with a further bandgap is selected from the following compounds:

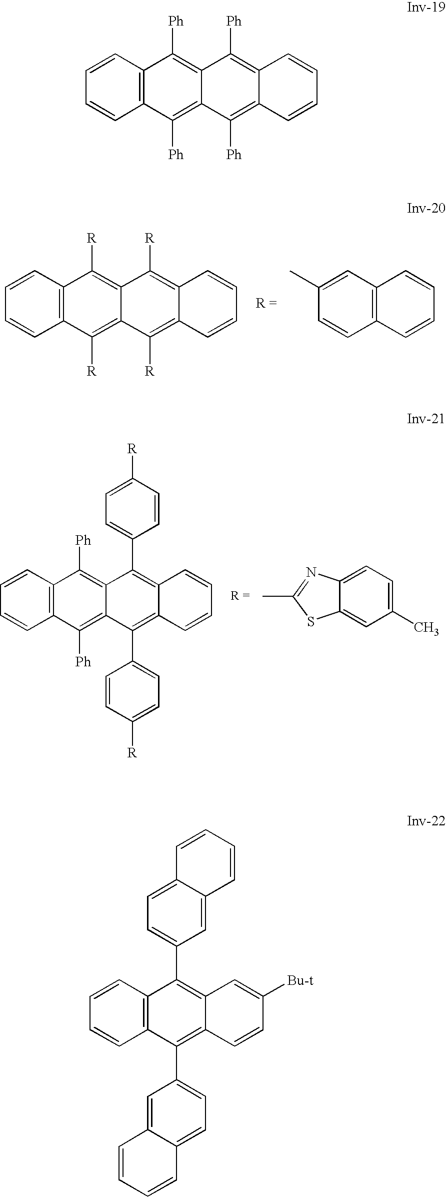

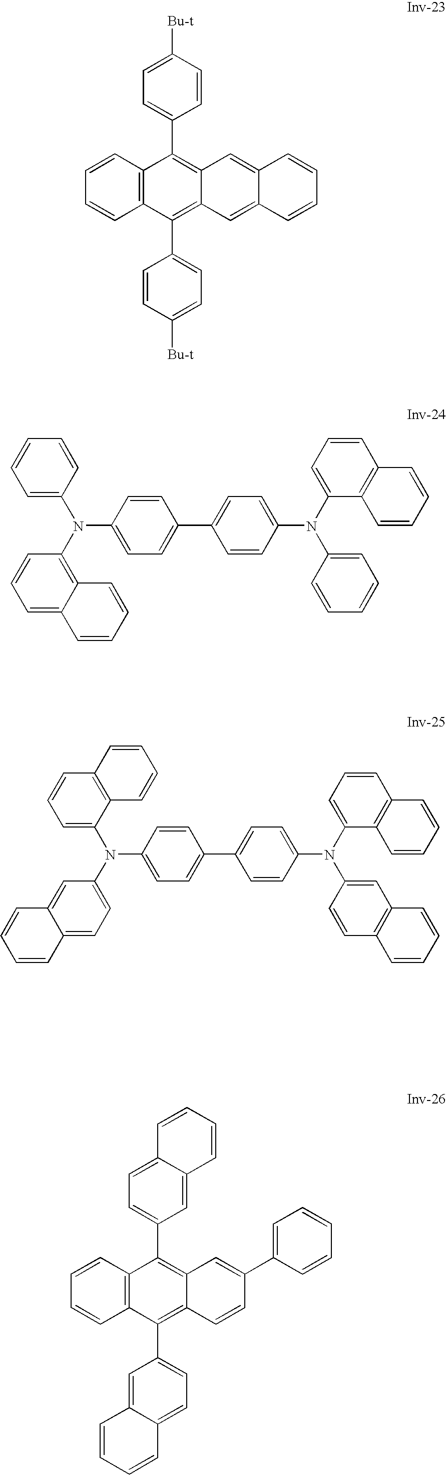

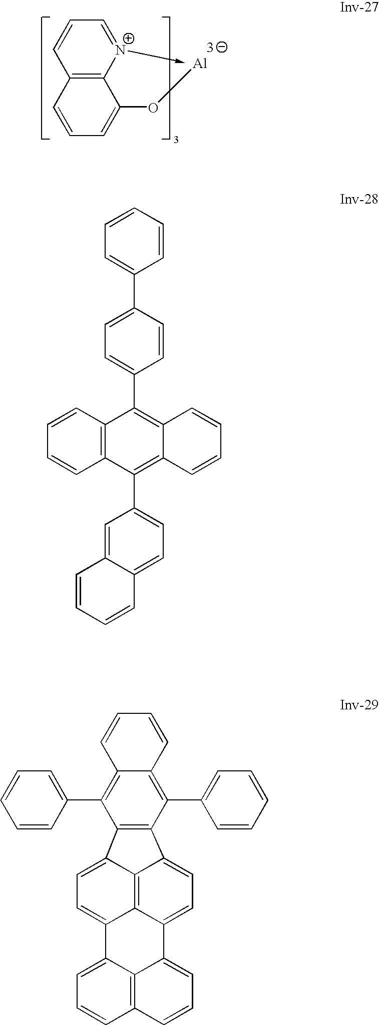

26. The OLED device of claim 1 wherein a non-electroluminescent component in the red light emitting layer with a further bandgap comprises more than one material selected from the following compounds:

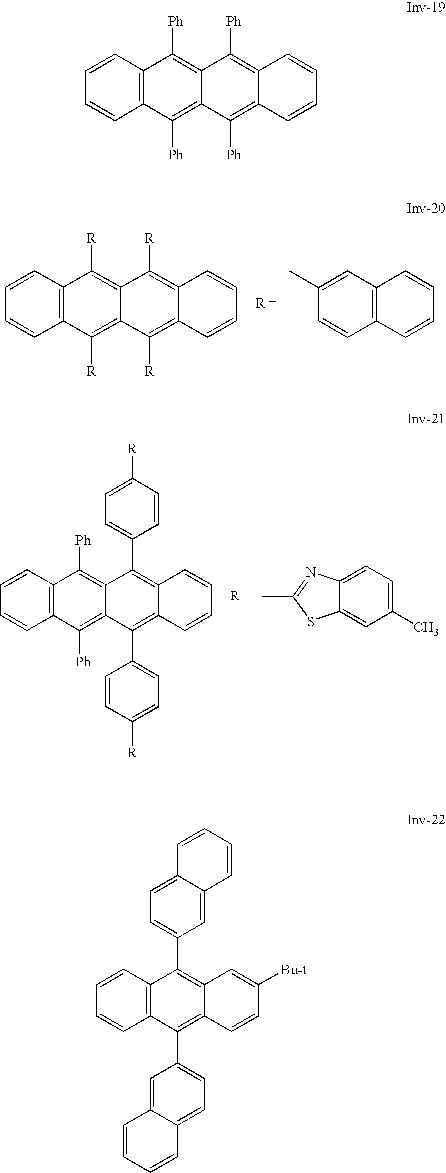

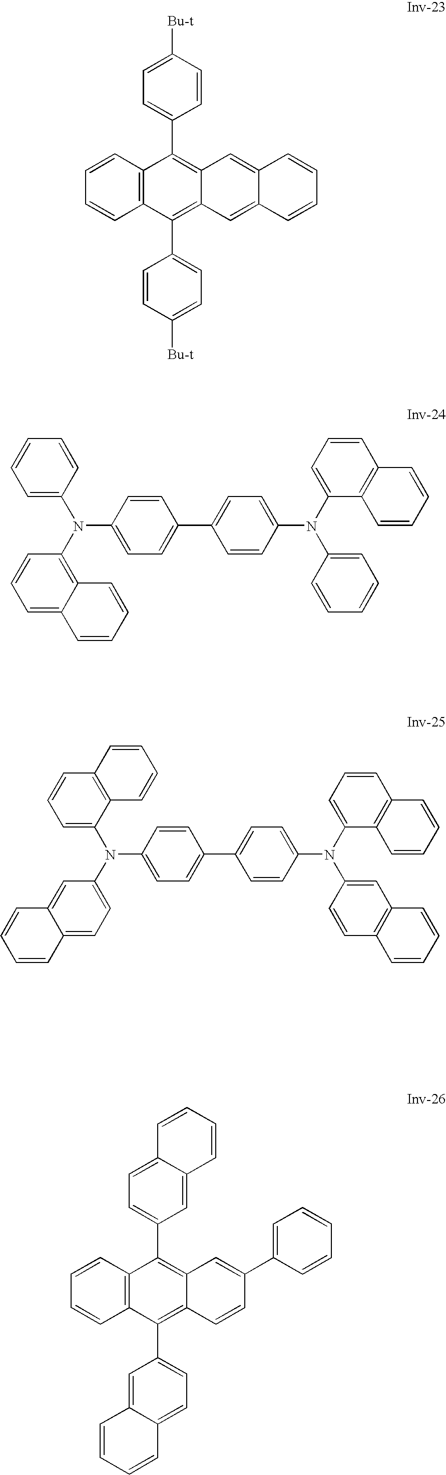

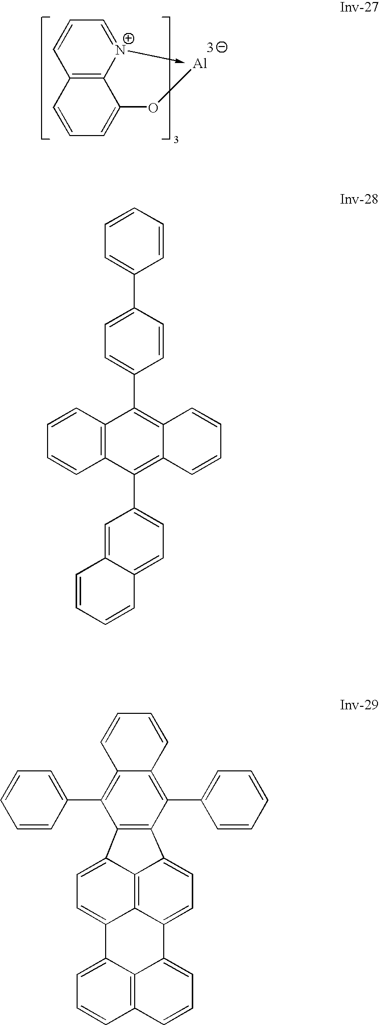

27. An OLED device of claim 1 wherein the blue light-emitting layer includes an electroluminescent distyrylamine compound.

28. An OLED device of claim 1 wherein the blue light emitting layer includes the electroluminescent distyrylamine compound as shown by the formula below, or its derivatives.

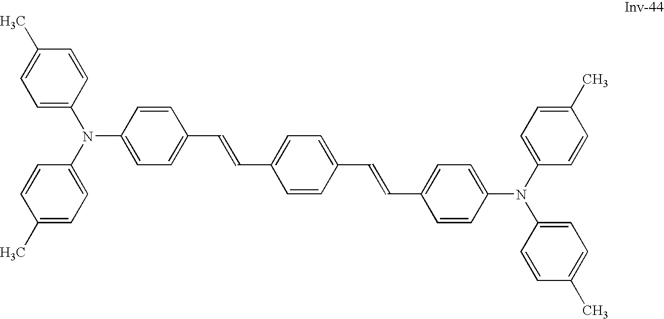

29. The OLED device of claim 1 wherein the blue light emitting layer includes a perylene compound or its derivatives.

30. The OLED device of claim 29 wherein the perylene derivative is 2,5,8,11-tetra-tert-butyl perylene (TBP).

31. The OLED device of claim 1 wherein the blue light emitting layer includes a bis(azinyl)amine boron complex.

32. The OLED device of claim 31 wherein the blue light emitting layer comprises at least one compound represented by the following formulae.

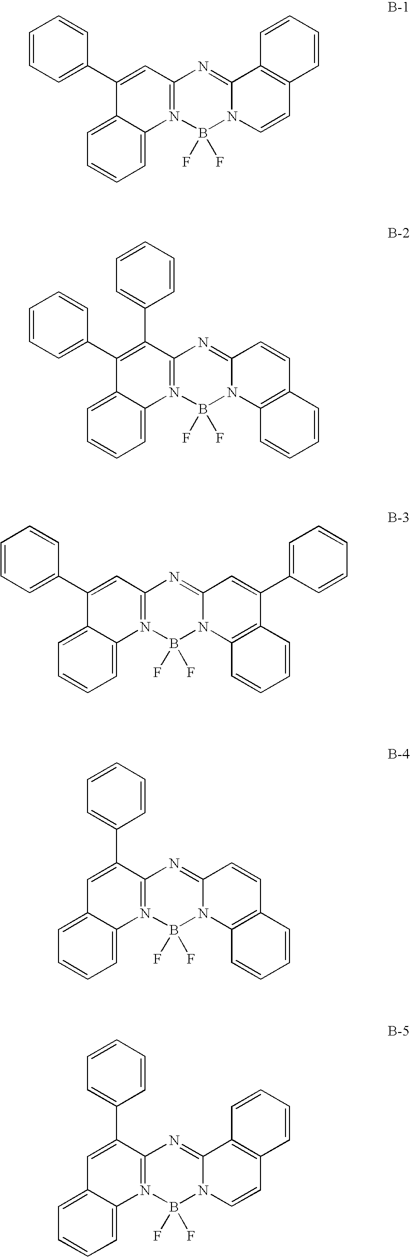

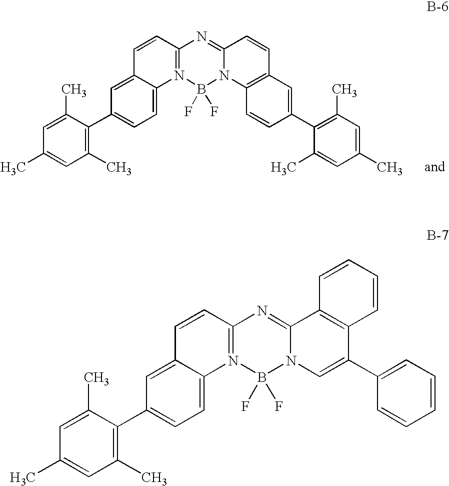

33. The OLED device of claim 1 wherein the blue-light emitting layer comprises at least one non-electroluminescent component and at least one blue-light electroluminescent component, wherein the concentration of said blue-light electroluminescent component is less than 20% of the non-electroluminescent component(s).

34. An OLED device comprising;
i) a substrate;
ii) an anode disposed over the substrate;
iii) a hole injecting layer disposed over the anode;
iv) a hole transport layer disposed over the hole injecting layer;
v) a blue light emitting layer;
vi) an electron transport layer disposed over the blue light emitting layer;
vii) a cathode disposed over the electron transport layer; and
viii) wherein the hole transport layer is a red light emitting layer as described in claim 1.

35. An OLED device of claim 34 wherein the hole transport layer is comprised of at least two sub layers and the sub layer closest to the blue emitting layer is the red light emitting sub layer.

36. An OLED device comprising;
i) a substrate;
ii) an anode disposed over the substrate;
iii) a hole injecting layer disposed over the anode;
iv) a hole transport layer disposed over the hole injecting layer;
v) a blue light emitting layer;
vi) an electron transport layer disposed over the blue light emitting layer;
vii) a cathode disposed over the electron transport layer; and
viii) wherein the electron transport layer is a red light emitting layer as described in claim 1.

37. An OLED device of claim 36 wherein the electron transport layer is comprised of at least two sub layers and the sub layer closest to the blue emitting layer is the red emittingsub layer.

38. An OLED device comprising;
i) a substrate;
ii) an anode disposed over the substrate;
iii) a hole injecting layer disposed over the anode;
iv) a hole transport layer disposed over the hole injecting layer;
v) a blue light emitting layer;
vi) an electron transport layer disposed over the blue light emitting layer;
vii) a cathode disposed over the electron transport layer; and
viii) wherein both an electron transport layer and a hole transport layer are red light emitting layers as described in claim 1.

39. An OLED device of claim 38 wherein the hole transport layer and the electron transport layer are each comprised of at least two sub layers and the sub layer closest to the blue light emitting layer are red light light emitting layers.

40. The OLED device of claim 1 wherein the non-electroluminescent components of the blue-light emitting layer are selected from the group consisting of: 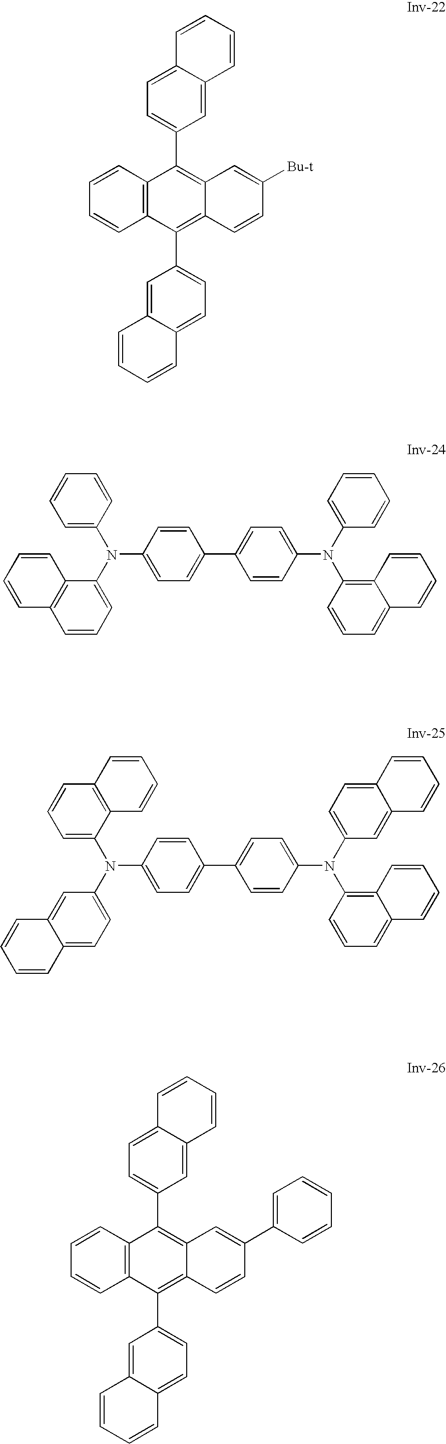 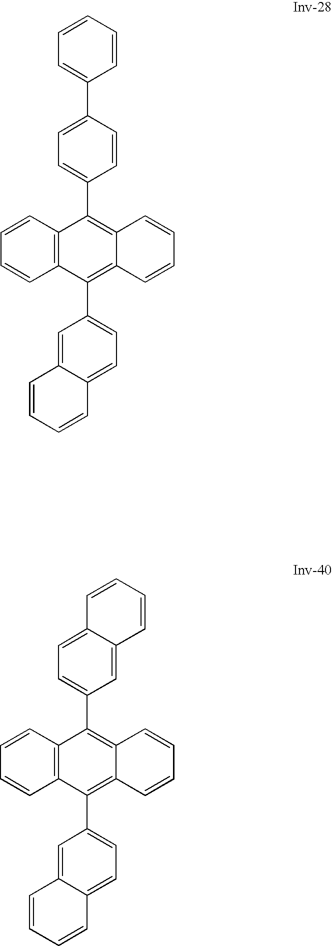
and the electroluminescent compounds of the blue-light emitting layer are selected from:

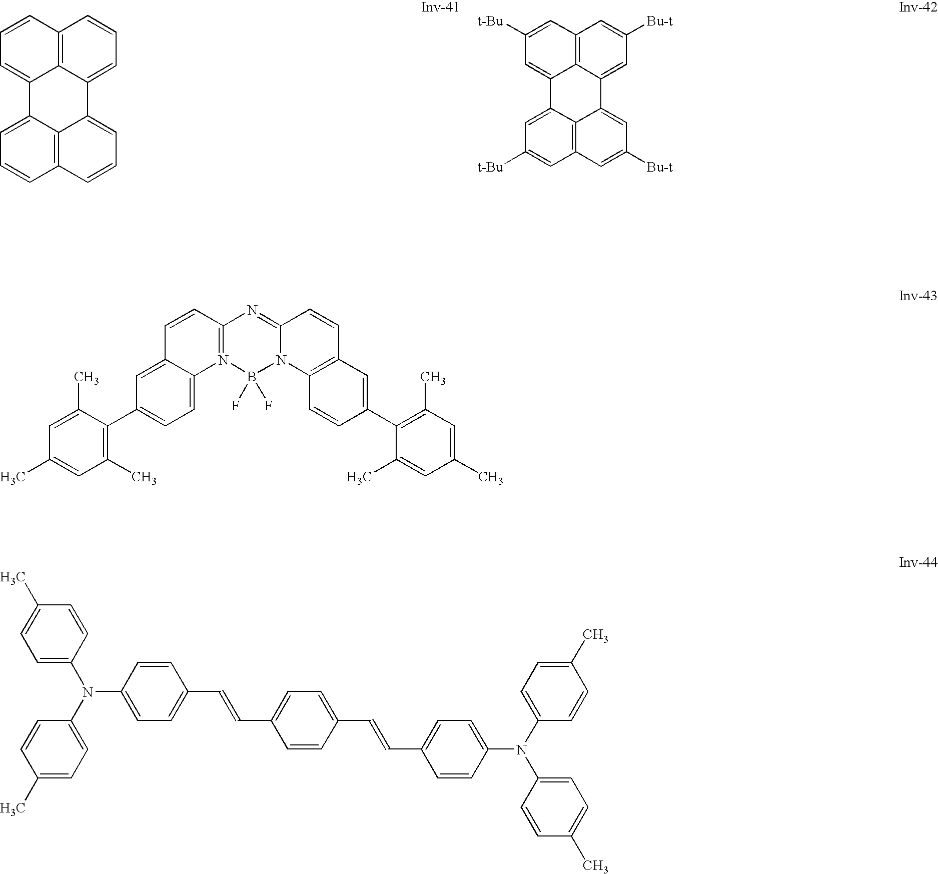

41. An OLED device that produces white light comprising (A) a red light emitting layer and (B) a blue light emitting layer wherein said red light emitting layer contains an electroluminescent component having a first bandgap, a non-electroluminescent component having a second bandgap, and one or more further non-electroluminescent components having further bandgaps, wherein:
i) the second bandgap is equal to or greater than the first bandgap but is not more than 2.7 eV;
ii) each of the further bandgaps are greater than the first and second bandgaps;
iii) the non-electroluminescent component with the second bandgap is present in an amount of 5 to 94.9 vol. percent of the total material in the light emitting layer;
iv) the one or more non-electroluminescent components with further bandgaps are present in a combined amount of 5 to 94.9 vol. percent of the total material in the light emitting layer and is selected from tris(8-quinolinolato)aluminum (III) (Alq₃); 2,2′,2′-(1,3,5-benzenetriyl)tris[1-phenyl-1H-benzimidazole] (TPBI); 2-tert-butyl-9,10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene;
v) the electroluminescent compound is present in amount of 0.1 to 5 vol. percent of the total material in the light emitting component; and
vi) the non-electroluminescent compound with the second bandgap is represented by formula (Ia); 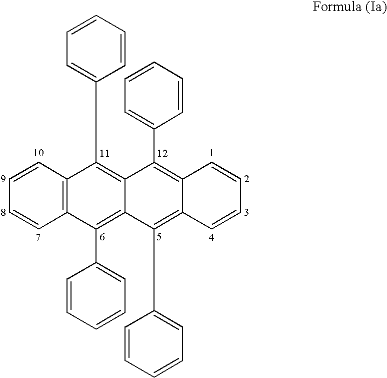
wherein:
a) any hydrogen on the phenyl rings in the 6- and 12-positions may be substituted;
b) there are identical substituent groups at the 2- and 8-positions; and
c) the phenyl rings in the 5- and 11-positions contain only para-substituents identical to the substituent groups in paragraph b).

42. An OLED device that produces white light comprising (A) a red light emitting layer and (B) a blue light emitting layer wherein said red light emitting layer contains an electroluminescent component having a first bandgap, a non-electroluminescent component having a second bandgap, and at least two further non-electroluminescent components having further bandgaps wherein:
i) the second bandgap is equal to or greater than the first bandgap but is not more than 2.7 eV;
ii) each of the further bandgaps is greater than the first and second bandgaps;
iii) the non-electroluminescent component with the second bandgap is present in an amount of 5 to 94.9 vol. percent of the total material in the light emitting layer;
iv) the at least two further non-electroluminescent components having further bandgaps are present in a combined amount of 5 to 94.9 vol. percent of the total material in the light emitting layer and at least one is selected from tris(8-quinolinolato)aluminum (III) (Alq₃); 2,2′,2′-(1,3,5-benzenetriyl)tris[1-phenyl-1H-benzimidazole] (TPBI); 2-tert-butyl-9, 10-bis(2-naphthyl)anthracene (TBADN); 5,6,11,12-tetraphenylnaphthacene (rubrene); N,N′-di-(1-naphthalenyl)-N,N′-diphenyl-4,4′-diamino(1,1′-biphenyl) (NPB); 4,4′-Bis[N-(1-naphthyl)-N-(2-naphthyl)amino]biphenyl(TNB); 5,12-bis[2-(5-methylbenzothiazolyl)phenyl]-6,11-diphenylnaphthacene (DBZR); 5,12-bis(4-tert-butylphenyl)naphthacene (tBDPN); 5,6,11,12-tetra-(2′-naphthalenyl)naphthacene (NR); 9,10-bis(2-naphthyl)-2-phenylanthracene; and 9-(2-naphthyl)-10-(4-phenyl)phenylanthracene;
v) the electroluminescent component is present in amount of 0.1 to 5 vol. percent of the total material in the light emitting component; and
vi) the non-electroluminescent component with the second bandgap is represented by formula (Ia); 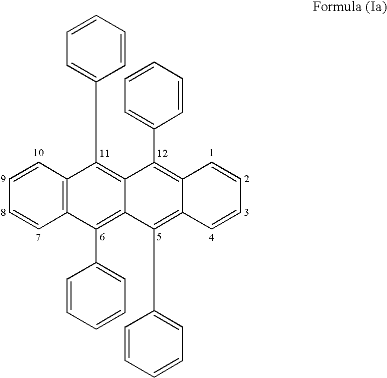
wherein:
a) any hydrogen on the phenyl rings in the 6- and 12-positions can be substituted;
b) there are identical substituent groups at the 2- and 8-positions; and
c) the phenyl rings in the 5- and 11-positions contain only para-substituents identical to the substituent groups in paragraph b).

43. A process for emitting light from the OLED device of claim 1 comprising applying a potential to the device.

44. A process for emitting light from the OLED device of claim 34 comprising applying a potential to the device.

45. A process for emitting light from the OLED device of claim 36 comprising applying a potential to the device.

46. A process for emitting light from the OLED device of claim 38 comprising applying a potential to the device.

47. The device of claim 1 wherein a hole-injecting layer is present between the anode and the hole-transporting layer.

48. The device of claim 47 wherein the hole-injecting layer comprises CFx, CuPC, or m-MTDATA.

49. The device of claim 1 wherein the cathode is selected from the group consisting of LiF/Al, Mg:Ag alloy, Al-Li alloy, and Mg-Al alloy.

50. The device of claim 1 wherein the cathode is transparent.

51. The device of claim 1 wherein the electron transport layer is transparent.

52. The device of claim 1 further including a buffer layer disposed on the cathode layer.

53. The device of claim 1 further including a color filter array disposed on the substrate or over the cathode.

54. The device of claim 53 further including a color filter array disposed on the buffer layer.

55. The device of claim 1 further including thin film transistors (TFTs) on the substrate, to address the individual pixels.

56. The device of claim 1 wherein the hole transport layer includes an aromatic tertiary amine.

57. The device of claim 1 wherein the hole transport layer includes a styryl amine.

58. The device of claim 7 wherein the hole transport layer includes an anthracene compound.

59. The device of claim 1 wherein the electron transport layer includes a copper phthalocyanine compound.
